(19) United States
(12) Patent Application Publication
(10) Pub. No.: US 2025/0324880 A1
(43) Pub. Date: Oct. 16, 2025

(54) DISPLAY DEVICE

(71) Applicant: Samsung Display Co., LTD., Yongin-si (KR)

(72) Inventors: Tae Young SONG, Yongin-si (KR); Bu Yong KIM, Yongin-si (KR); Soo Dong KIM, Yongin-si (KR); Jin Won KIM, Yongin-si (KR); Hye Jin PAEK, Yongin-si (KR)

(73) Assignee: Samsung Display Co., LTD., Yongin-si (KR)

(21) Appl. No.: 18/982,058

(22) Filed: Dec. 16, 2024

(30) Foreign Application Priority Data
Apr. 11, 2024 (KR) 10-2024-0048639

(51) Int. Cl. H10K 59/38; H10K 59/122; H10K 59/35; H10K 59/80

(52) U.S. Cl. CPC H10K 59/38; H10K 59/122; H10K 59/353; H10K 59/873; H10K 59/8792

(57) ABSTRACT

A display device having increased emission efficiency and increased aperture ratio. The display device may include a substrate, a pixel circuit layer disposed on the substrate and including a pixel circuit, a bank layer disposed on the pixel circuit layer and including a first opening, a light emitting element including a light emitting layer disposed inside the first opening, an encapsulation layer covering the light emitting element, a black matrix disposed on the light emitting element and including a second opening, a light functional layer disposed inside the second opening, a color filter layer including a third opening surrounded by a nested structure where first to third color filters overlap, one of the first to third color filters may be disposed in the third opening, and a spacer disposed at least partially overlap the second opening.

### CROSS-REFERENCE TO RELATED APPLICATION(S)

This application claims priority under 35 U.S.C. 119 to and benefits of Korean Patent Application No. 10-2024-0048639 filed on Apr. 11, 2024 in the Korean Intellectual Property Office, the entire contents of which are incorporated herein by reference.

### BACKGROUND

### 1. Technical Field

Embodiments of the disclosure relate to a display device.

### 2. Description of the Related Art

As information technology develops, importance of a display device which is a connection medium between a user and information, is being highlighted. In response to this, a use of the display device such as a liquid crystal display device (LCD) and an organic light emitting display device is increasing.

The display device may be formed by bonding a display panel in which a pixel circuit and a light emitting element are disposed and an optical panel in which a color filter is disposed. In a process of bonding the display panel and the optical panel, the pixel circuit and/or the light emitting element may be damaged, or the color filter may be damaged. In order to prevent this, the display panel and/or optical panel may include a spacer.

### SUMMARY

A technical object to be solved is to provide a display device capable of protecting a display panel and an optical panel.

A technical object to be solved is to provide a display device with an increased aperture ratio.

A technical object to be solved is to provide a display device with an increased emission efficiency.

Embodiments of the disclosure may provide a display device. The display device may include a substrate, a pixel circuit layer disposed on the substrate and including a pixel circuit, a bank layer disposed on the pixel circuit layer and including a first opening, a light emitting element including a light emitting layer disposed inside the first opening, an encapsulation layer covering the light emitting element, a black matrix disposed on the light emitting element and including a second opening, a light functional layer disposed inside the second opening, a color filter layer including a first color filter, a second color filter, and a third color filter, the color filter layer further including a third opening surrounded by a nested structure where the first to third color filters overlap, wherein one of the first to third color filters may be disposed in the third opening, and a spacer, wherein at least a portion of the spacer may overlap the second opening.

The spacer may further overlap at least one of the first opening and the third opening.

The light functional layer may include a first functional layer overlapping the first color filter and that converts to light of a first wavelength band and emit light of the first wavelength band, a second functional layer overlapping the second color filter and that converts to light of a second wavelength band different from the first wavelength band and emit light of the second wavelength band, and a third functional layer overlapping the third color filter and that scatters light.

The first wavelength band may be a red wavelength band, and the second wavelength band may be a green wavelength band.

The third opening may correspond to an emission area, and at least a portion of the spacer may overlap the emission area.

The display device may further include a filling layer, a display panel including the substrate and the encapsulation layer, and an optical panel including the color filter layer, the filling layer may be disposed between the display panel and the optical panel, and the spacer may be surrounded by the filling layer.

The display panel may further include the spacer.

The spacer may contact the encapsulation layer and may be covered by the filling layer.

The display panel may include the black matrix, a passivation layer, and the light functional layer, the passivation layer may cover the black matrix and the light functional layer, and the spacer may be disposed between the passivation layer and the filling layer.

The optical panel may include the spacer.

The spacer may contact the color filter layer and the spacer may be covered by the filling layer.

The optical panel may include the black matrix and the light functional layer, the optical panel may further include a passivation layer covering the black matrix and the light functional layer, and the spacer may be disposed between the passivation layer and the filling layer.

The first opening may be surrounded by a sloped first edge portion of the bank layer, and the spacer may overlap the sloped first edge portion of the bank layer.

The second opening may be surrounded by a sloped second edge portion of the black matrix, and the spacer may overlap the sloped second edge portion of the black matrix.

The spacer may overlap a side end portion of the nested structure.

A plurality of pixels may be disposed on the substrate and may be adjacent to each other in a first direction, each of the plurality of pixels may include a first sub-pixel including the first color filter, a second sub-pixel including the second color filter, and a third sub-pixel including the third color filter, and at least a portion of the spacer may overlap the third opening of one of the first to third sub-pixels in a plan view.

An entirety of the spacer may overlap the third opening of one of the first to third sub-pixels in a plan view.

The spacer may overlap a third opening of at least two of the first to third sub-pixels.

The first sub-pixel and the third sub-pixel may be adjacent to each other in the first direction, the third opening of each of the first sub-pixel and the second sub-pixel may have a trapezoidal shape in a plan view, the third opening of the third sub-pixel may have a rectangular shape, and the third openings in a pixel including the first to third sub-pixels may generally have a rectangular shape.

Each of the first sub-pixel and the second sub-pixel may further extend in a second direction perpendicular to the first direction, and each of the first sub-pixel and the second sub-pixel may be adjacent to the third sub-pixel in the second direction.

### BRIEF DESCRIPTION OF THE DRAWINGS

The above and other features of the disclosure will become more apparent by describing in further detail embodiments thereof with reference to the accompanying drawings, in which:

FIG. 1 is a schematic plan view of a display device according to embodiments of the disclosure;

FIG. 2 is a schematic cross-sectional view taken along line I-I′ of the display device of FIG. 1;

FIG. 3 is a schematic plan view of an embodiment of a display area;

FIGS. 4 to 7 are examples of schematic cross-sectional views taken along line II-II′ of FIG. 3;

FIG. 8 is a schematic plan view of an embodiment of the display area;

FIGS. 9 to 12 are examples of schematic cross-sectional views taken along line III-III′ of FIG. 8;

FIG. 13 is a schematic plan view of still an embodiment of the display area;

FIGS. 14 to 17 are examples of schematic cross-sectional views taken along line IV-IV′ of FIG. 13;

FIG. 18 is a schematic plan view of further still an embodiment of the display area;

FIGS. 19 to 22 are examples of schematic cross-sectional views taken along line V-V′ of FIG. 18;

FIG. 23 is an embodiment in which sub-pixels are disposed in the display area;

FIGS. 24A to 26B are modified embodiments of FIG. 23;

FIGS. 27 to 29 are schematic cross-sectional views of an embodiment of the display area;

FIG. 30 is an embodiment in which the sub-pixels are disposed in the display area;

FIGS. 31A to 35 are modified embodiments of FIG. 30;

FIG. 36 is still an embodiment in which the sub-pixels are disposed in the display area;

FIGS. 37A to 52 are modified embodiments of FIG. 36;

FIGS. 53 to 64 are other examples of schematic cross-sectional views taken along line II-II′ of FIG. 3;

FIGS. 65 and 66 are schematic diagrams illustrating different shapes of a spacer disposed in the display area; and

FIG. 67 is a schematic diagram of an equivalent circuit of a sub-pixel according to embodiments of the disclosure.

### DETAILED DESCRIPTION OF THE EMBODIMENTS

In the following description, for the purposes of explanation, numerous specific details are set forth in order to provide a thorough understanding of various embodiments or implementations of the disclosure. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the disclosure. Therefore, unless otherwise specified, the features, components, modules, layers, films, panels, regions, and/or aspects, etc., (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals and/or reference characters denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may be different directions that are not perpendicular to one another.

For the purposes of this disclosure, “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc., may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, parts, and/or modules. Those skilled in the art will appreciate that these blocks, parts, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, parts, and/or modules being implemented by microprocessors or other similar hardware, they may be programmed and controlled using software (e.g., microcode) to perform various functions discussed herein and may optionally be driven by firmware and/or software. It is also contemplated that each block, part, and/or module may be implemented by dedicated hardware, or as a combination of dedicated hardware to perform some functions and a processor (e.g., one or more programmed microprocessors and associated circuitry) to perform other functions. Also, each block, part, and/or module of some embodiments may be physically separated into two or more interacting and discrete blocks, parts, and/or modules without departing from the scope of the inventive concepts. Further, the blocks, parts, and/or modules of some embodiments may be physically combined into more complex blocks, parts, and/or modules without departing from the scope of the inventive concepts.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

Hereinafter, embodiments of the disclosure are described in detail with reference to the accompanying drawings.

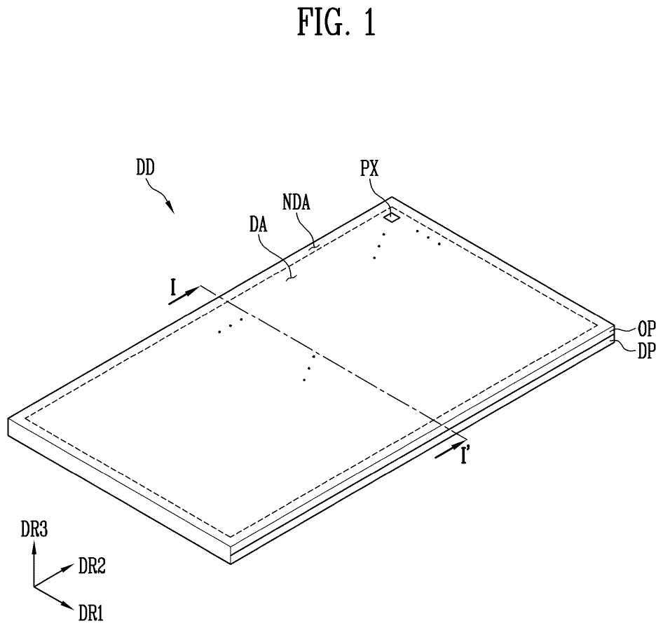

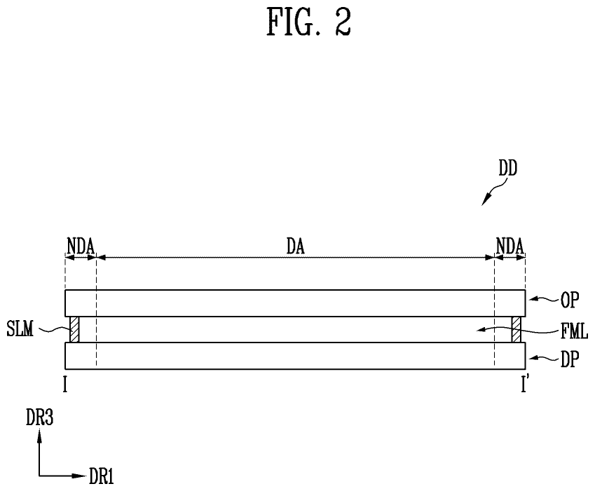

FIG. 1 is a schematic plan view of a display device DD according to embodiments of the disclosure. FIG. 2 is a schematic cross-sectional view taken along line I-I′ of the display device DD of FIG. 1.

The display device DD according to embodiments of the disclosure may be a device that may be activated according to an electrical signal. For example, the display device DD may be a mobile phone, a tablet, a car navigation system, a game console, a wearable device, or the like, but embodiments of the disclosure are not limited thereto.

The display device DD according to embodiments of the disclosure may include a display area DA and a non-display area NDA positioned around the display area DA (for example, at an edge area (or edge portion) of the display area DA). The display area DA may correspond to a portion where an image may be displayed. Multiple pixels PX may be disposed in the display area DA. Each of the pixels PX may include multiple sub-pixels configured to emit light of different wavelength bands.

In an embodiment, a shape of the display area DA may be a quadrangular shape. The non-display area NDA may be configured to surround the display area DA. However, embodiments of the disclosure are not limited thereto. For example, the shape of the display area DA may be implemented as a polygonal shape, a circular shape, or the like other than a quadrangular square.

In the display device DD according to embodiments of the disclosure, the pixels PX may be adjacent to each other in a direction (e.g., single direction) in the display area DA. Referring to FIG. 1, the pixels PX may be adjacent to each other in a first direction DR1. For example, the pixels PX may be adjacent to each other in a second direction DR2 different from the first direction DR1 (for example, perpendicular to the first direction DR1). However, embodiments of the disclosure are not limited thereto. For example, the pixels PX may be adjacent to each other in a direction (e.g., single direction) different from the first direction DR1 and the second direction DR2.

The display device DD according to embodiments of the disclosure may include a display panel DP and an optical panel OP. A filling layer FML may be disposed between the display panel DP and the optical panel OP. The display panel DP and the optical panel OP may be disposed to face each other in a third direction DR3. The third direction DR3 may be a thickness direction of each of the display panel DP and the optical panel OP, and may be perpendicular to the first direction DR1 and the second direction DR2.

The filling layer FML may be configured to fill between the display panel DP and the optical panel OP. The filling layer FML may function as a buffer between the display panel DP and the optical panel OP. In an embodiment, the filling layer FML may function to absorb shock and increase a strength of the display device DD. For example, the filling layer FML may include a filling resin including a polymer resin. The polymer resin configuring the filling layer FML may have light transmittance. The filling layer FML may be formed of a filling layer resin including, for example, an acrylic resin or an epoxy resin. However, embodiments of the disclosure are not limited thereto.

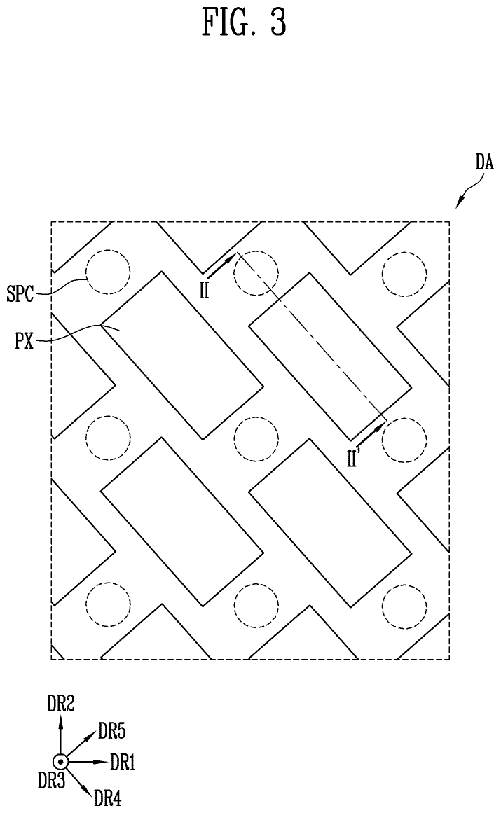

The display device DD according to embodiments of the disclosure may include a bonding portion SLM disposed between the display panel DP and the optical panel OP. The bonding portion SLM may be configured to couple the display panel DP and the optical panel OP to each other. The bonding portion SLM may be disposed in the non-display area NDA, which may be an outer area (or an edge area or an edge portion) of the display device DD. The bonding portion SLM may include a sealant including a curable resin. In an embodiment, the bonding portion SLM may include an epoxy resin, an acrylic resin, or the like. The sealant may be formed of a thermoset material or a photocurable material. The sealant may be provided on a surface (e.g., single surface) of the display panel DP or the optical panel OP, and may be configured to form the bonding portion SML by being cured by heat or ultraviolet light after bonding the display panel DP and the optical panel OP so that the display panel DP and the optical panel OP face each other (for example, face each other in the third direction DR3). FIG. 3 is a schematic plan view of an embodiment of the display area DA.

Referring to FIG. 3, multiple pixels PX may be disposed in the display area DA. The pixels PX may be adjacent to each other in the first direction DR1 and the second direction DR2.

Each of the pixels PX may generally have a rectangular shape (or close to a rectangular shape). Referring to FIG. 3, each of the pixels PX may have a long side extending in a fourth direction DR4 and a short side extending in a fifth direction DR5. The fourth direction DR4 may be a direction indicated by rotating a clockwise direction from the first direction DR1 by an angle (e.g., predetermined or selectable angle). The fifth direction DR5 may be a direction indicated by rotating a clockwise direction from the second direction DR2 by an angle (e.g., predetermined or selectable angle). In the above embodiment, the pixels PX may be adjacent to each other in the fourth direction DR4. The fourth direction DR4 and the fifth direction DR5 may be perpendicular to each other. However, referring to FIG. 3, the shape of the pixel PX may be disclosed as being generally rectangular shape, but embodiments of the disclosure are not limited thereto. For example, the shape of the pixel PX may have a quadrangular shape other than a rectangular shape, or may have a polygonal shape other than a rectangular shape.

Referring to FIG. 3, a spacer SPC may be disposed between the pixels PX adjacent to each other in the fourth direction DR4.

The spacer SPC may be configured to provide a margin (e.g., predetermined or selectable margin) in the third direction DR3 so that the pixel PX may not be damaged in a process of bonding the display panel DP and the optical panel OP described above. The spacer SPC may be disposed in the display area DA.

Referring to FIG. 3, the spacer SPC may be disposed outside the pixel PX.

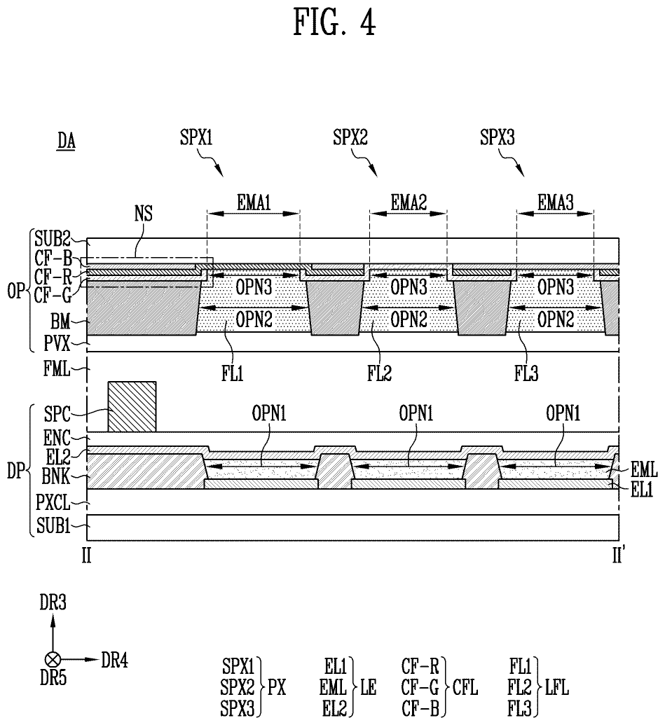

FIGS. 4 to 7 are examples of a schematic cross-sectional view taken along line II-II′ of FIG. 3.

Referring to FIG. 4, the display panel DP, the filling layer FML, and the optical panel OP may be shown on a schematic cross-sectional view of the display area DA.

Referring to FIG. 4, the display panel DP may include a first substrate SUB1, a pixel circuit layer PXCL, a bank BNK, a light emitting element LE, an encapsulation layer ENC, a spacer SPC, and the like.

The first substrate SUB1 may be formed of an insulating material such as glass or resin. For example, the first substrate SUB1 may include a glass substrate. As another example, the first substrate SUB1 may include a polyimide (PI) substrate. As still another example, the first substrate SUB1 may include a silicon wafer substrate formed using a semiconductor process.

In embodiments, the first substrate SUB1 may be formed of a material having flexibility material that may be bent or folded. In embodiments, the first substrate SUB1 may have a single-layer or multi-layer structure. For example, the material having flexibility may include at least one of polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, cellulose acetate propionate, or a combination thereof. However, embodiments of the disclosure are not limited thereto.

The pixel circuit layer PXCL may be disposed on the first substrate SUB1. The pixel circuit layer PXCL may include insulating layers and active patterns and conductive patterns disposed between the insulating layers. The conductive patterns of the pixel circuit layer PXCL may function as circuit elements, lines, and the like.

The lines of the pixel circuit layer PXCL may include lines connected to each of the sub-pixels. The lines of the pixel circuit layer PXCL may include a power line, a gate line, a data line, and the like.

A bank BNK may be disposed on the pixel circuit layer PXCL. The bank BNK may be configured to include a light blocking material to prevent light mixing between adjacent sub-pixels. In embodiments, the bank BNK may include an inorganic material. In the above embodiment, the bank BNK may include an inorganic layer (for example, multiple stacked inorganic layers). For example, the bank BNK may include silicon oxide (SiOₓ) and/or silicon nitride (SiNₓ). In other embodiments, the bank BNK may include an organic layer including an organic material. For example, the bank BNK may include an organic insulating material such as acryl resin, epoxy resin, phenol resin, polyamide resin, and polyimide resin.

The bank BNK may include a first opening OPN1 exposing at least a portion of a first electrode EL1.

The light emitting element LE may be disposed on the pixel circuit layer PXCL. The light emitting element LE may include the first electrode EL1, a light emitting layer EML, and a second electrode EL2. The first electrode EL1 may configure an electrode (for example, an anode electrode) of the light emitting element LE. The anode electrode AE may include at least one of light transmitting (for example, transparent) conductive materials such as indium tin oxide (ITO), indium zinc oxide (IZO), zinc oxide (ZnOₓ), indium gallium zinc oxide (IGZO), indium tin zinc oxide (ITZO), or a combination thereof. The zinc oxide (ZnOₓ) may be zinc oxide (ZnO) and/or zinc peroxide (ZnO₂). However, a material of the anode electrode AE is not limited thereto. For example, the anode electrode AE may include titanium nitride.

The light emitting layer EML may form excitons since holes injected from the first electrode EL1 and electrons injected from the second electrode EL2 may be transported into the light emitting layer EML, and in case that the excitons are transited form an excited state to a ground state, light may be generated. A luminance of light may be determined according to an amount of a current flowing through the light emitting layer EML. According to a configuration of the light emitting layer EML, a wavelength band of the light generated in the light emitting layer EML may be determined. In an embodiment, the light emitting layer EML may be formed through a process such as vacuum deposition or inkjet printing. However, a method of forming the light emitting layer EML is not limited to that described above.

Referring to FIG. 4, the first electrode EL1 and the light emitting layer EML may be positioned inside the first opening OPN1. However, embodiments of the disclosure are not limited thereto. For example, at least a portion of the light emitting layer EML may extend outside the first opening OPN1 and may be entirely disposed in the display area DA.

The second electrode EL2 may be formed of a metal material to have a relatively thin thickness or may be formed of a light transmitting (for example, transparent) conductive material. In embodiments, the second electrode EL2 may include at least one of various transparent conductive materials including indium tin oxide (ITO), indium zinc oxide (IZO), indium tin zinc oxide (ITZO), aluminum zinc oxide, gallium zinc oxide, zinc tin oxide, or gallium tin oxide. However, a material configuring the second electrode EL2 according to embodiments of the disclosure is not limited to that described above. The second electrode EL2 may function as a half mirror that partially transmits and partially reflects the light emitted from the light emitting layer EML.

The encapsulation layer ENC may be disposed on the second electrode EL2. The encapsulation layer ENC may cover the light emitting element LE and/or the pixel circuit layer PXCL. The encapsulation layer ENC may be configured to prevent oxygen and/or moisture from permeating into the light emitting element LE. In embodiments, the encapsulation layer ENC may include a structure in which one or more inorganic layers and one or more organic layers may be alternately stacked on each other. For example, the inorganic layer may include silicon nitride, silicon oxide, silicon oxynitride (SiOₓN_{y}), or a combination thereof. For example, the organic layer may include an organic insulating material such as acrylic resin (polyacrylates resin), epoxy resin, phenolic resin, polyamides resin, polyimides resin, unsaturated polyester resin, polyphenylene resin, polyphenylene sulfide resin, benzocyclobutene (BCB), or a combination thereof. However, materials of the organic layer and the inorganic layer of the encapsulation layer ENC are not limited to that described above.

In order to improve an encapsulation efficiency of the encapsulation layer ENC, the encapsulation layer ENC may further include a thin film including aluminum oxide (AlOₓ). The thin film including aluminum oxide may be positioned on an upper surface of the encapsulation layer ENC facing the optical panel OP and/or on a lower surface of the encapsulation layer ENC facing the light emitting element LE. The thin film including aluminum oxide may be formed through atomic layer deposition (ALD). However, embodiments of the disclosure are not limited thereto. The encapsulation layer ENC may further include a thin film formed of at least one of various materials suitable for improving the encapsulation efficiency.

The spacer SPC may be positioned on the encapsulation layer ENC. The spacer SPC may be formed using a photoresist process or an inkjet process. According to an embodiment, the spacer SPC may have a light transmittance. However, according to an embodiment, the spacer SPC may have a light-shielding property. For example, the spacer SPC may include a black pigment.

The filling layer FML may be formed from a filling resin including a polymer resin. The filling layer FML may include acrylic resin, epoxy resin, or the like.

The optical panel OP may include a second substrate SUB2, a color filter layer CFL, a black matrix BM, a light functional layer LFL, and a passivation layer PVX.

The second substrate SUB2 may be a member configured to provide a base surface on which the color filter layer CFL may be disposed. The second substrate SUB2 may be formed of an insulating material such as glass or resin. For example, the second substrate SUB2 may include a glass substrate. As another example, the second substrate SUB2 may include a polyimide (PI) substrate. In embodiments, the second substrate SUB2 may be formed of a material having flexibility that may be bent or folded.

The color filter layer CFL may be configured to filter the light emitted from the light emitting layer EML and selectively output light of a wavelength band corresponding to each of the sub-pixels SPX1, SPX2, and SPX3. The color filter layer CFL may include color filters CF-R, CF-G, and CF-B respectively corresponding to the sub-pixels SPX1, SPX2, and SPX3. Each of the color filters CF-R, CF-G, and CF-B may pass light of a wavelength band corresponding to a corresponding sub-pixel. For example, the first color filter CF-R corresponding to the first sub-pixel SPX1 may pass light of a first wavelength band (for example, a red wavelength band). The second color filter CF-G corresponding to the second sub-pixel SPX2 may pass light of a second wavelength band (for example, a green wavelength band). The third color filter CF-B corresponding to the third sub-pixel SPX3 may pass light of a third wavelength band (for example, a blue wavelength band).

The red wavelength band may be in a range of about 630 to about 750 nanometers (nm). The green wavelength band may be in a range of about 495 to about 570 nm. The blue wavelength band may be in a range of about 450 to about 495 nm.

In embodiments, the color filters CF-R, CF-G, and CF-B may overlap (for example, partially overlap) in a boundary area between the first to third sub-pixels. Referring to FIG. 4, the color filter layer CFL may include a nested structure NS in which the first color filter CF-R, the second color filter CF-G, and the third color filter CF-B overlap.

In an embodiment, the color filter layer CFL may be formed by sequentially stacking the third color filter CF-B, the first color filter CF-R, and the second color filter CF-G on the second substrate SUB2. However, embodiments of the disclosure are not limited thereto, and an order in which the first to third color filters CF-R, CF-G, and CF-B may be stacked may be freely changed.

The nested structure NS may function to block light by overlapping the first to third color filters CF-R, CF-G, and CF-B.

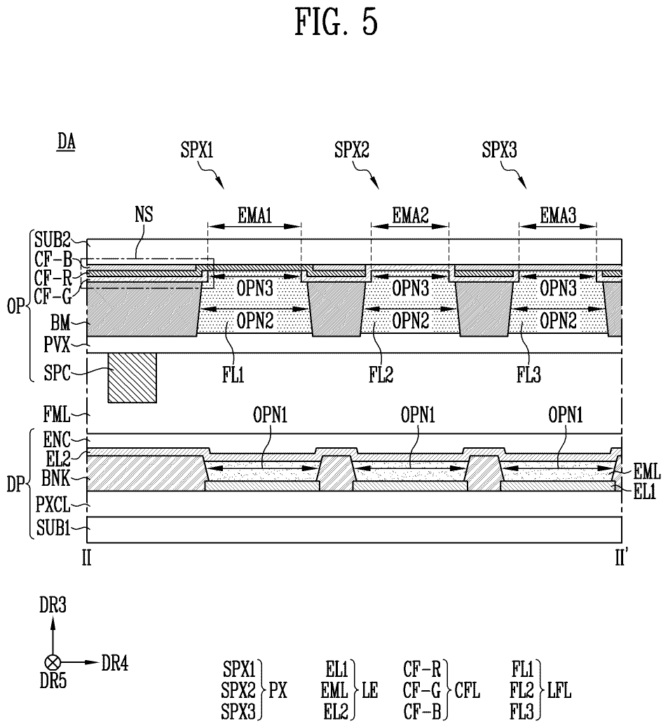

Referring to FIG. 5, the color filter layer CFL may include a third opening OPN3 defined as an area between the nested structures NS. One of the first to third color filters CF-R, CF-G, and CF-B may be positioned in the third opening OPN3.

The black matrix BM may include a second opening OPN2 from which at least a portion of the black matrix BM may be removed. The light functional layer LFL may be positioned inside the second opening OPN2. The black matrix BM may be configured to include a light-blocking material and may prevent light mixing between adjacent sub-pixels SPX1, SPX2, and SPX3. In embodiments, the black matrix BM may include an organic material. For example, black matrix BM may include an organic insulating material such as acrylic resin, epoxy resin, phenol resin, polyamide resin, polyimide resin, or a combination thereof.

The light functional layer LFL may include color conversion particles and/or scattering particles. The color conversion particles may change a wavelength of incident light and convert the incident light into light of a different color. The color conversion particles may scatter incident light. In embodiments, the color conversion particles may be quantum dots. The scattering particles may scatter incident light.

The first sub-pixel SPX1 may be a red sub-pixel. In case that the light emitting element LE of the first sub-pixel SPX1 emits the light of the blue wavelength band, the first sub-pixel SPX1 may include a first functional layer FL1 configured to convert the light of the blue wavelength band into the light of the red wavelength band. In case that the light emitting element LE of the first sub-pixel SPX1 emits the light of the red wavelength band, the first sub-pixel SPX1 may include a first functional layer FL1 configured to scatter light. As described above, according to a wavelength band of light emitted by the light emitting element LE of the first sub-pixel SPX1, particles included in the first functional layer FL1 may be variously changed. The first functional layer FL1 may include a quantum dot. The first functional layer FL1 may be formed through an inkjet process.

The second sub-pixel SPX2 may be a green sub-pixel. In case that the light emitting element LE of the second sub-pixel SPX2 emits the light of the blue wavelength band, the second sub-pixel SPX2 may include a second functional layer FL2 configured to convert the light of the blue wavelength band into the light of the green wavelength band. In case that the light emitting element LE of the second sub-pixel SPX2 emits the light of the green wavelength band, the second sub-pixel SPX2 may include a second functional layer FL2 configured to scatter light. As described above, according to a wavelength band of light emitted by the light emitting element LE of the second sub-pixel SPX2, particles included in the second functional layer FL2 may be variously changed. The second functional layer FL2 may include a quantum dot. The second functional layer FL2 may be formed through an inkjet process.

A shape of the above-described quantum dot may be a spherical shape, a pyramidal shape, a multi-arm shape, or a shape of a cubic nanoparticle, nanotube, nanowire, nanofiber, nanoplate particle, and the like. However, embodiments of the disclosure are not limited thereto.

The third sub-pixel SPX3 may be a blue sub-pixel. In case that the light emitting element LE of the third sub-pixel SPX3 emits the light of the blue wavelength band, the third sub-pixel SPX3 may include a third functional layer FL3 configured to scatter light. The third functional layer FL3 may include oxide of titanium, silver, aluminum, or any combination thereof.

The passivation layer PVX may be configured to protect the light functional layer LFL. In an embodiment, the passivation layer PVX may include an organic capping layer and an inorganic capping layer. For example, the organic capping layer may be formed by inkjet. The inorganic capping layer may be formed on the organic capping layer.

In an embodiment, the light functional layer LFL and the organic capping layer may be formed by simultaneously crosslinking the light functional layer LFL and the organic capping layer (for example, with ultraviolet light of about 390 nm wavelength for less than one minute).

In an embodiment, the inorganic capping layer may be formed on the organic capping layer and the black matrix BM in a vapor chemical deposition method. The inorganic capping layer may be configured of a layer including silicon (Si), nitrogen (N), a combination thereof, or an oxide thereof. For example, the inorganic capping layer may have a thickness of about 100 to about 1,000 nm.

In each of the sub-pixels SPX1, SPX2, and SPX3, an area where the first to third openings OPN1, OPN2, and OPN3 overlap (for example, overlap in the third direction DR3 or in a plan view) may be defined as a multi-overlap area. Referring to FIG. 4, an area where the first to third openings OPN1, OPN2, and OPN3 overlap each other in the third direction DR3 in the first sub-pixel SPX1 may be defined as a first multi-overlap area. An area where the first to third openings OPN1, OPN2, and OPN3 overlap each other in the third direction DR3 in the second sub-pixel SPX2 may be defined as a second multi-overlap area. An area where the first to third openings OPN1, OPN2, and OPN3 overlap each other in the third direction DR3 in the third sub-pixel SPX3 may be defined as a third multi-overlap area.

The third opening OPN3 corresponds to an area where light may be emitted. The third opening OPN3 may correspond to an emission area where light may be substantially emitted from the sub-pixel. An area other than the emission area in the display area DA may be referred to as a non-emission area.

Referring to FIG. 4, the spacer SPC may be disposed on the display panel DP. The spacer SPC may be formed on the encapsulation layer ENC through an inkjet or photoresist process.

The spacer SPC may be disposed between the encapsulation layer ENC and the filling layer FML.

Referring to FIG. 5, the spacer SPC may be disposed on the optical panel OP. The spacer SPC may be formed on the passivation layer PVX through an inkjet or photoresist process.

The spacer SPC may be disposed between the passivation layer PVX and the filling layer FML.

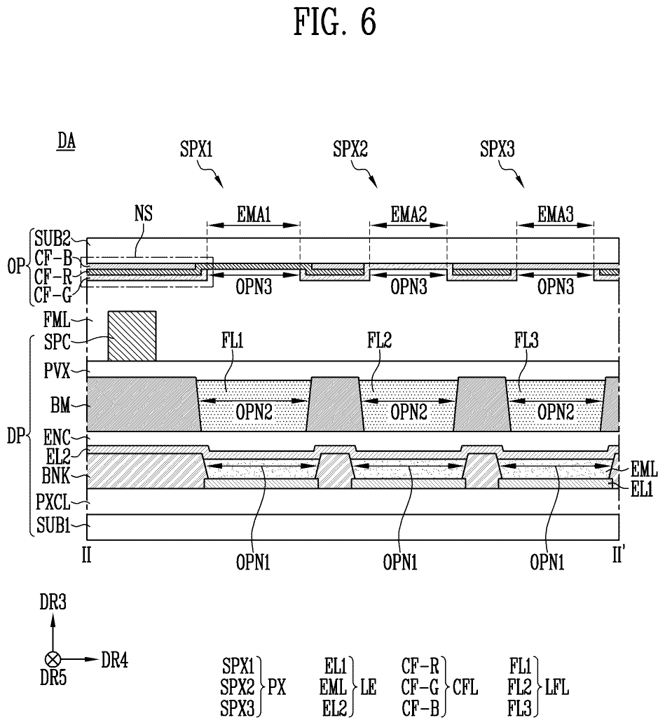

Referring to FIG. 6, the display panel DP may include the black matrix BM, the light functional layer LFL, the passivation layer PVX, and the spacer SPC. The optical panel OP may include the color filter layer CFL and the second substrate SUB2.

In the embodiment shown in FIG. 6, the black matrix BM may be formed on the encapsulation layer ENC. The black matrix BM may include a second opening OPN2 formed by removing at least a partial area of the encapsulation layer ENC.

The light functional layer LFL may be disposed inside the second opening OPN2.

The passivation layer PVX may be disposed on the black matrix BM and the light functional layer LFL.

The spacer SPC may be disposed on the passivation layer PVX. The spacer SPC may be disposed between the passivation layer PVX and the filling layer FML. The spacer SPC may be formed on the passivation layer PVX through an inkjet or photoresist process.

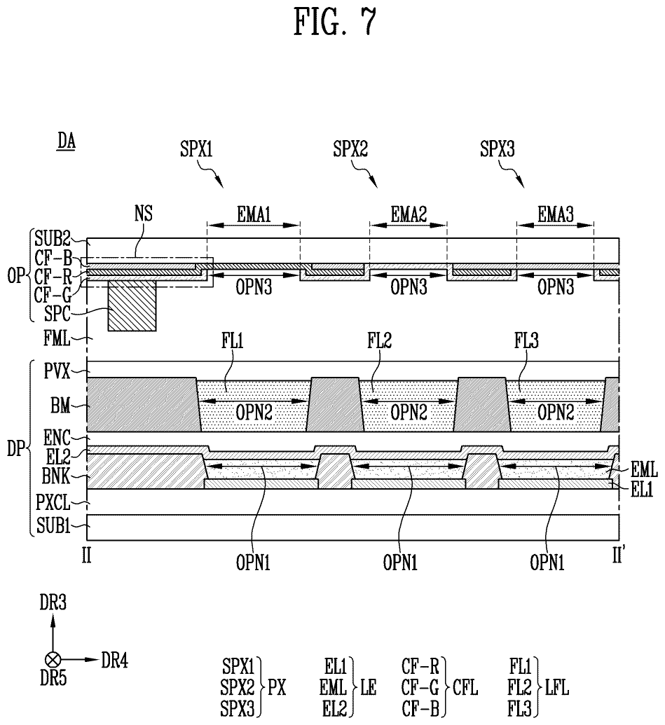

Referring to FIG. 7, the display panel DP may include the black matrix BM, the light functional layer LFL, and the passivation layer PVX. The optical panel OP may include the color filter layer CFL, the second substrate SUB2, and the spacer SPC.

In the embodiment shown in FIG. 7, the spacer SPC may be disposed on the color filter layer CFL. The spacer SPC may be formed on the color filter layer CFL through an inkjet or photoresist process. In an embodiment, the spacer SPC may be disposed (e.g., directly disposed) on the overlap structure NS.

The spacer SPC may be disposed between the color filter layer CFL and the filling layer FML.

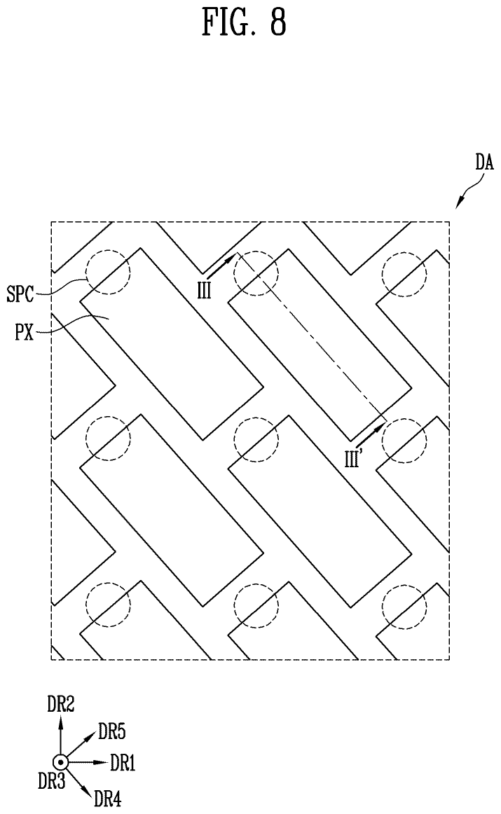

FIG. 8 is a schematic plan view of an embodiment of the display area DA.

Referring to FIG. 8, at least a portion of the spacer SPC may overlap the pixel PX. A meaning that at least a portion of the spacer SPC overlaps the pixel PX may indicate that at least a portion of the spacer SPC overlaps the emission area of the sub-pixels configuring the pixel PX.

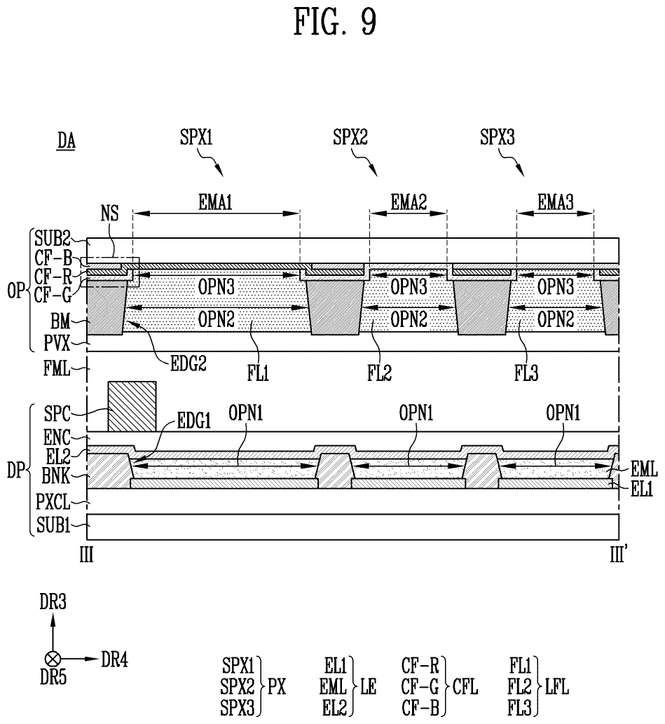

FIGS. 9 to 12 are examples of a schematic cross-sectional view taken along line III-III′ of FIG. 8.

Referring to FIG. 9, at least a portion of the spacer SPC may overlap the emission area. Referring to FIG. 9, at least a portion of the spacer SPC may overlap a first emission area EMA1. However, embodiments of the disclosure are not limited thereto. For example, at least a portion of the spacer SPC may overlap a second emission area EMA2 or may overlap a third emission area EMA3.

The spacer SPC may overlap a first edge portion EDG1 of the bank BNK. The first edge portion EDG1 may configure a side surface of the first opening OPN1. At least a portion of the spacer SPC may overlap the first opening OPN1.

The spacer SPC may overlap a second edge portion EDG2 of the black matrix BM. The second edge portion EDG2 may configure a side surface of the second opening OPN2. At least a portion of the spacer SPC may overlap the second opening OPN2.

The spacer SPC may overlap a side end portion (e.g., single side end portion) of the overlap structure NS. A side end (e.g., single side end) of the overlap structure NS may configure a side surface of the third opening OPN3. At least a portion of the spacer SPC may overlap the third opening OPN3.

According to embodiments of the disclosure, the entire area of the emission areas EMA1, EMA2, and EMA3 may be increased. Accordingly, emission efficiency of the sub-pixels SPX1, SPX2, and SPX3 may be increased.

According to the embodiment shown in FIG. 9, the spacer SPC may be disposed between the encapsulation layer ENC and the filling layer FML. The spacer SPC may be included in the display panel DP.

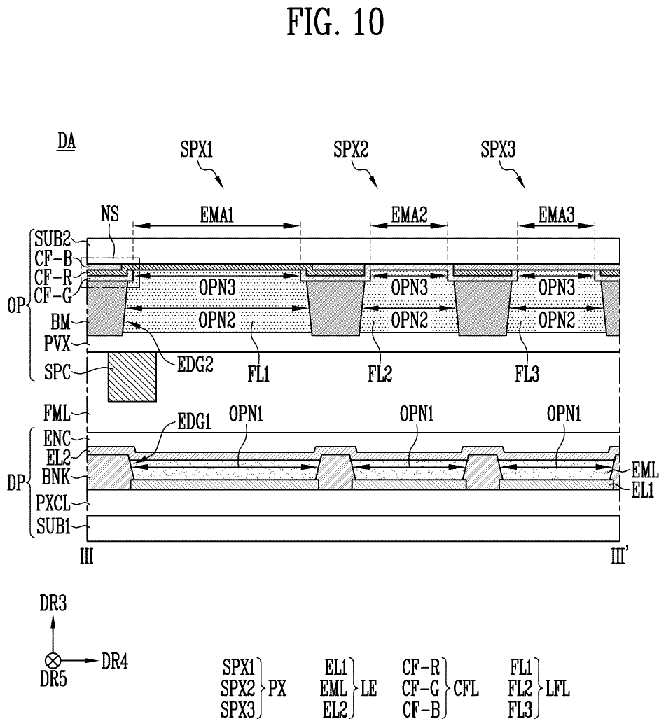

Referring to FIG. 10, the spacer SPC may be disposed between the passivation layer PVX and the filling layer FML. At least a portion of the spacer SPC may overlap at least one of the first to third openings OPN1, OPN2, and OPN3. The spacer SPC may be included in the optical panel OP.

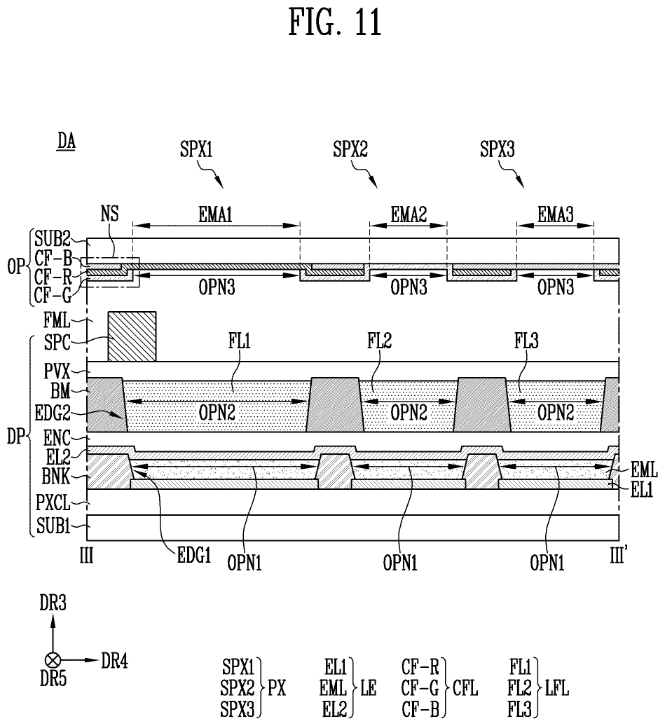

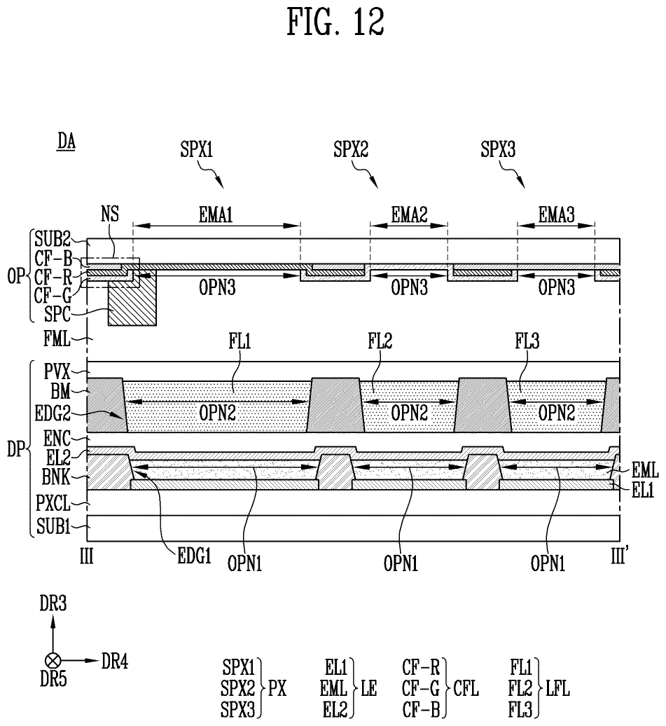

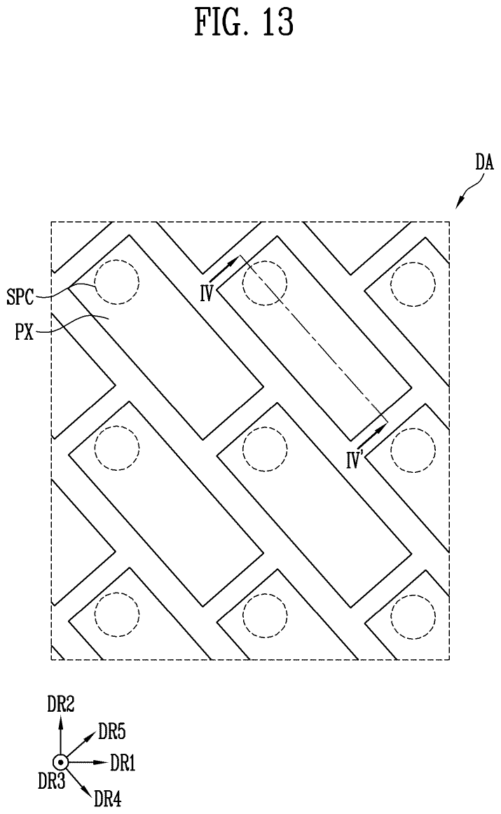

Referring to FIG. 11, the spacer SPC may be disposed between the passivation layer PVX and the filling layer FML. At least a portion of the spacer SPC may overlap at least one of the first to third openings OPN1, OPN2, and OPN3. The spacer SPC may be included in the display panel DP.

Referring to FIG. 12, the spacer SPC may be disposed between the color filter layer CFL and the filling layer FML. At least a portion of the spacer SPC may overlap at least one of the first to third openings OPN1, OPN2, and OPN3. The spacer SPC may be included in the optical panel OP.

At least a portion of the spacer SPC may cover the a side end portion (e.g., single side end portion) of the overlap structure NS. At least a portion of the spacer SPC may be positioned inside the third opening OPN3.

In an embodiment, at least a portion of the spacer SPC may be positioned inside the third opening OPN3 of the first sub-pixel SPX1. However, embodiments of the disclosure are not limited thereto. For example, at least a portion of the spacer SPC may be positioned inside the third opening OPN3 of the second sub-pixel SPX2, or may be positioned inside the third opening OPN3 of the third sub-pixel SPX3.

FIG. 13 is a schematic plan view of still an embodiment of the display area DA.

Referring to FIG. 13, the spacer SPC may be positioned generally (or entirely) overlap the pixel PX. A meaning that the spacer SPC generally (or entirely) overlaps the pixel PX may indicate that the entire spacer SPC overlaps the emission area of the sub-pixels configuring the pixel PX.

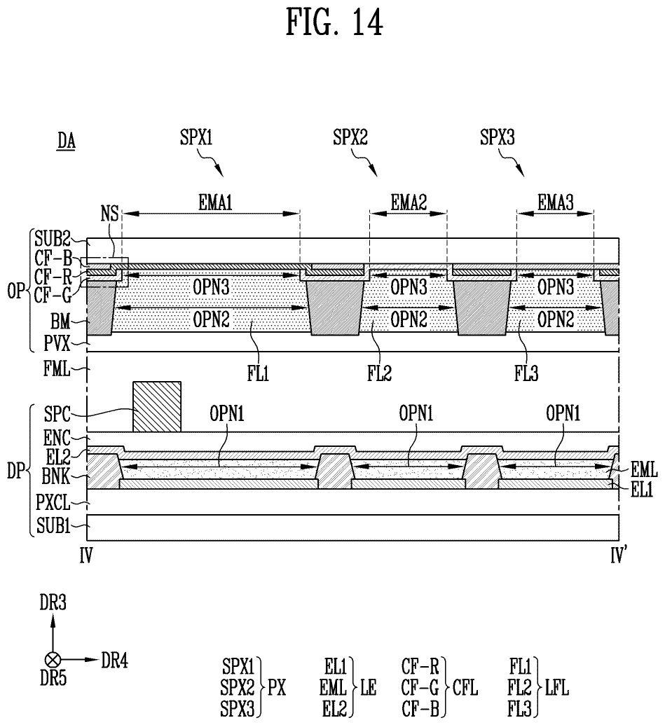

FIGS. 14 to 17 are examples of a schematic cross-sectional view taken along line IV-IV′ of FIG. 13.

Referring to FIG. 14, the spacer SPC may entirely overlap the emission area. Referring to FIG. 14, an entirety of the spacer SPC may overlap the first emission area EMA1. However, embodiments of the disclosure are not limited thereto. For example, an entirety of the spacer SPC may overlap the second emission area EMA2 or may overlap the third emission area EMA3.

The spacer SPC may overlap the third opening OPN3 corresponding to the emission area. However, embodiments of the disclosure are not limited thereto, and the spacer SPC may overlap the first opening OPN1 and/or the second opening OPN2.

According to embodiments of the disclosure, the entire area of the emission areas EMA1, EMA2, and EMA3 may be increased. Accordingly, emission efficiency of the sub-pixels SPX1, SPX2, and SPX3 may be increased.

According to the embodiment shown in FIG. 14, the spacer SPC may be disposed between the encapsulation layer ENC and the filling layer FML. The spacer SPC may be included in the display panel DP.

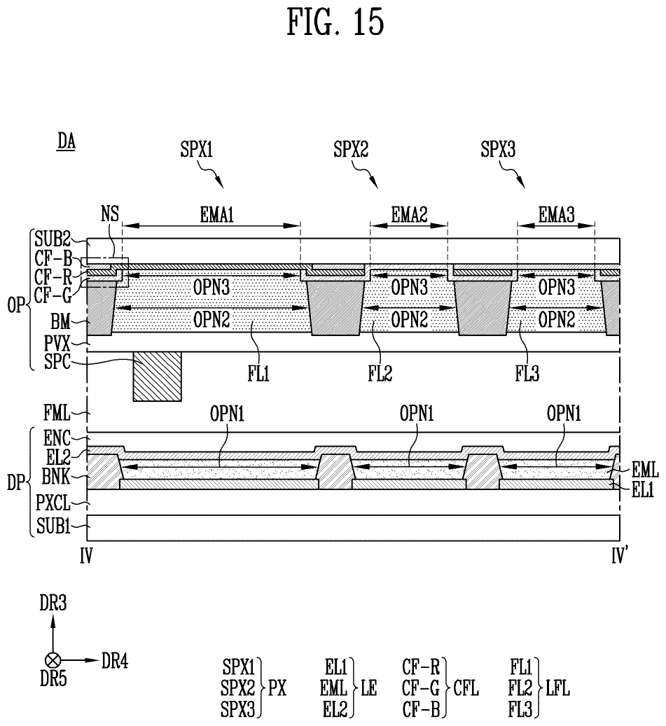

Referring to FIG. 15, the spacer SPC may be disposed between the passivation layer PVX and the filling layer FML. The spacer SPC may be positioned to entirely overlap the first to third openings OPN1, OPN2, and OPN3. The spacer SPC may be included in the optical panel OP.

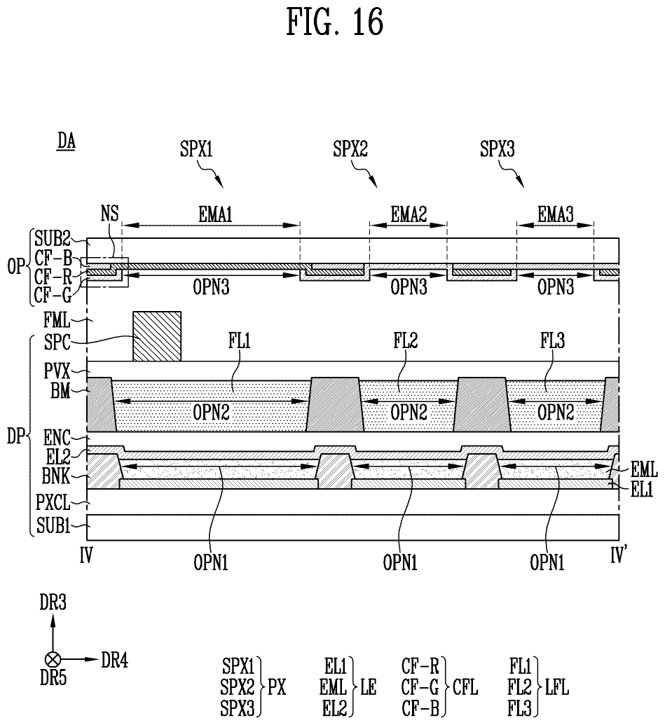

Referring to FIG. 16, the spacer SPC may be disposed between the passivation layer PVX and the filling layer FML. The spacer SPC may be positioned to entirely overlap the first to third openings OPN1, OPN2, and OPN3. The spacer SPC may be included in the display panel DP.

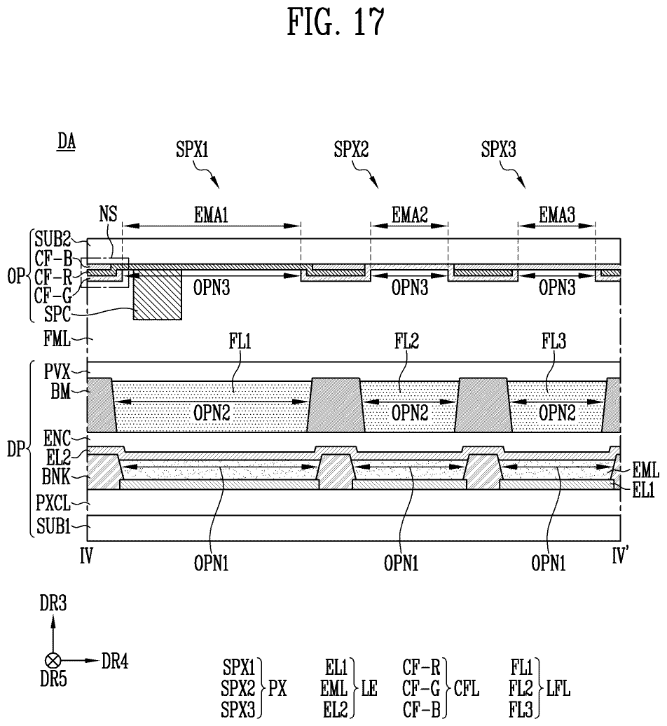

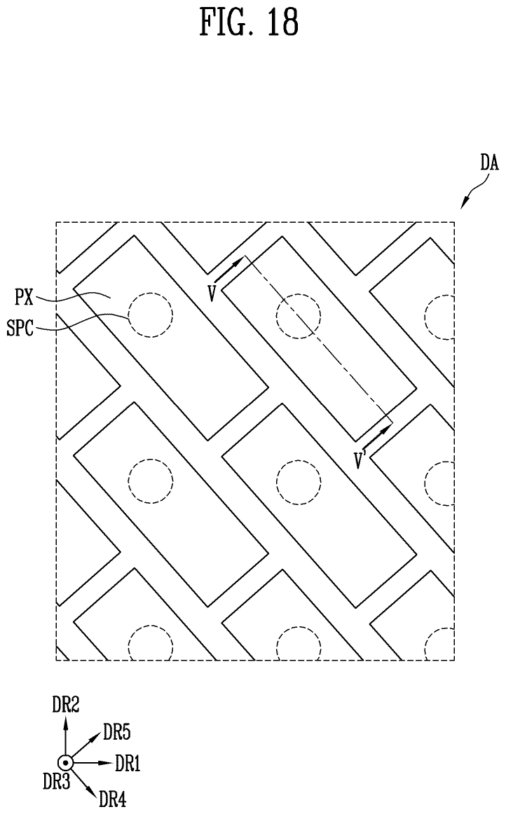

Referring to FIG. 17, the spacer SPC may be disposed between the color filter layer CFL and the filling layer FML. The spacer SPC may be positioned to entirely overlap the first to third openings OPN1, OPN2, and OPN3. The spacer SPC may be included in the optical panel OP.

The spacer SPC may be disposed (e.g., directly disposed) on an upper surface of one of the first to third color filters CF-R, CF-G, and CF-B. For example, referring to FIG. 17, the spacer SPC may overlap the first color filter CF-R and may not overlap the second and third color filters CF-G and CF-B. However, embodiments of the disclosure are not limited thereto. For example, the spacer SPC may overlap the second color filter CF-G and may not overlap the first and third color filters CF-R and CF-B. For example, the spacer SPC may overlap the third color filter CF-B and may not overlap the first and second color filters CF-G and CF-B.

In the above embodiment, the spacer SPC may be entirely positioned inside the third opening OPN3 of the first sub-pixel SPX1. However, embodiments of the disclosure are not limited thereto. For example, the spacer SPC may be entirely positioned inside the third opening OPN3 of the second sub-pixel SPX2, or may be positioned inside the third opening OPN3 of the third sub-pixel SPX3.

FIG. 18 is a schematic plan view of an embodiment of the display area DA.

Referring to FIG. 18, the spacer SPC may be positioned inside the pixel PX. A meaning that the spacer SPC may be positioned inside the pixel PX may indicate that the spacer SPC may be disposed between (or at a boundary area) multiple sub-pixels.

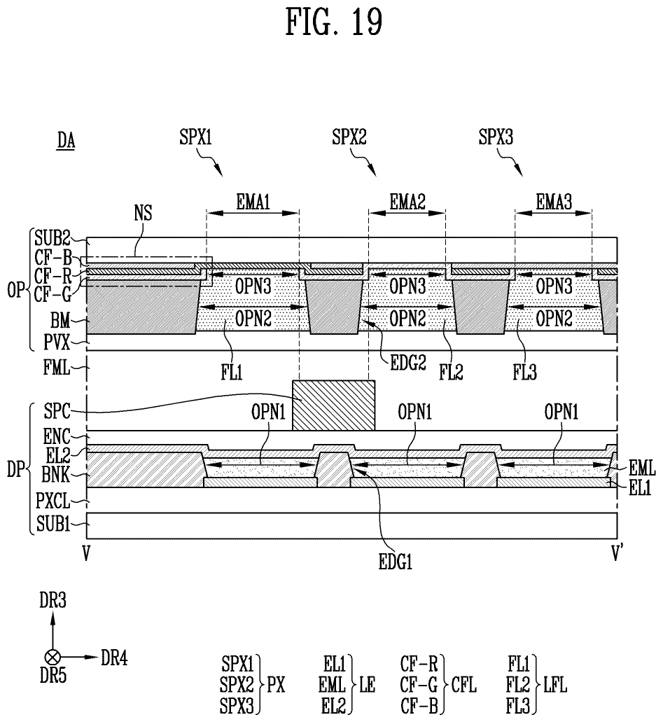

FIGS. 19 to 22 are examples of a schematic cross-sectional view taken along line V-V′ of FIG. 18.

In embodiments of the disclosure, the spacer SPC may be positioned inside the pixel PX of FIG. 18, and may be positioned in a boundary area between the sub-pixels SPX1, SPX2, and SPX3.

Referring to FIG. 19, the spacer SPC may be positioned at a boundary area between the first sub-pixel SPX1 and the second sub-pixel SPX2. Referring to FIG. 19, at least a portion of the spacer SPC may overlap the first emission area EMA1, at least a portion of the spacer SPC may overlap the bank BNK and/or the black matrix BM, and the remaining portion of the spacer SPC may overlap the second emission area EMA2. However, embodiments of the disclosure are not limited thereto. For example, the spacer SPC may be positioned in a boundary area between the first and third sub-pixels SPX1 and SPX3, or may be disposed in a boundary area between the second and third sub-pixels SPX2 and SPX3.

According to an embodiment, the spacer SPC may be positioned in the boundary area between the first to third sub-pixels SPX1, SPX2, and SPX3. In the above embodiment, the spacer SPC may overlap the first to third emission areas EMA1, EMA2, and EMA3.

The spacer SPC may be entirely positioned to overlap the first to third openings OPN1, OPN2, and OPN3.

In embodiments of the disclosure, the spacer SPC may overlap the first edge portion EDG1 of the bank BNK and/or the second edge portion EDG2 of the black matrix BM.

According to embodiments of the disclosure, the entire area of the emission areas EMA1, EMA2, and EMA3 may be increased. Accordingly, emission efficiency of the sub-pixels SPX1, SPX2, and SPX3 may be increased.

According to the embodiment shown in FIG. 19, the spacer SPC may be disposed between the encapsulation layer ENC and the filling layer FML. The spacer SPC may be included in the display panel DP.

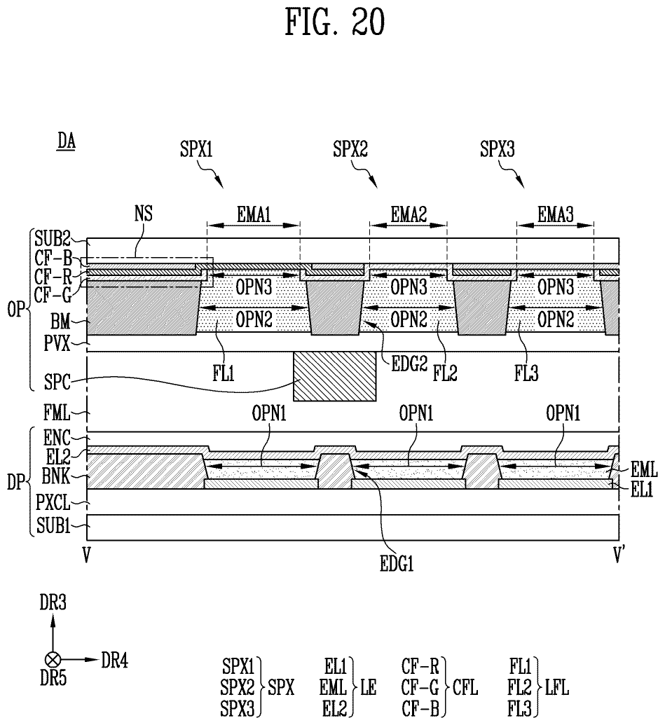

Referring to FIG. 20, the spacer SPC may be disposed between the passivation layer PVX and the filling layer FML. The spacer SPC may overlap at least two of the first to third emission areas EMA1, EMA2, and EMA3. The spacer SPC may be included in the optical panel OP.

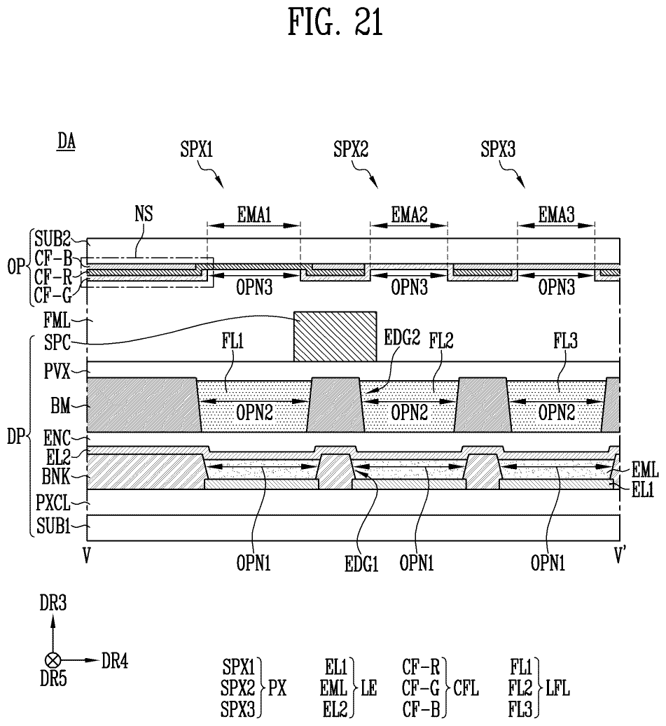

Referring to FIG. 21, the spacer SPC may be disposed between the passivation layer PVX and the filling layer FML. The spacer SPC may overlap at least two of the first to third emission areas EMA1, EMA2, and EMA3. The spacer SPC may be included in the display panel DP.

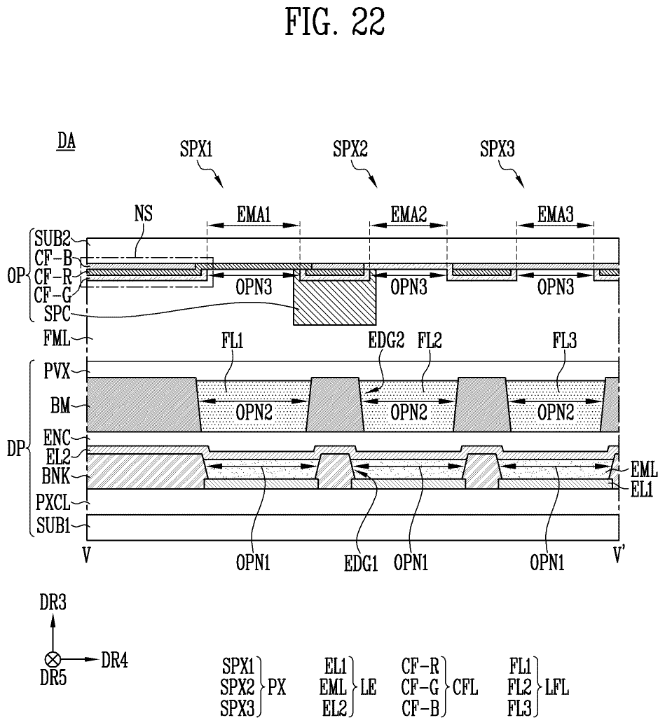

Referring to FIG. 22, the spacer SPC may be disposed between the color filter layer CFL and the filling layer FML. The spacer SPC may overlap at least two of the first to third emission areas EMA1, EMA2, and EMA3. The spacer SPC may be included in the optical panel OP.

The spacer SPC may be disposed (e.g., directly disposed) on an upper surface of at least two of the first to third color filters CF-R, CF-G, and CF-B. For example, referring to FIG. 22, the spacer SPC may overlap the first and second color filters CF-R and CF-G and may not overlap the third color filter CF-B. However, embodiments of the disclosure are not limited thereto. For example, the spacer SPC may overlap the first and third color filters CF-R and CF-B and may not overlap the second color filter CF-G. For example, the spacer SPC may overlap the second and third color filters CF-G and CF-B and may not overlap the first color filter CF-R.

At least a portion of the spacer SPC may be positioned on the overlap structure NS. A portion of a remainder of the spacer SPC may be positioned inside the third opening OPN3 of the first sub-pixel SPX1, and another portion of the remainder of the spacer SPC may be positioned inside the third opening OPN3 of the second sub-pixel SPX2. However, embodiments of the disclosure are not limited thereto. For example, the spacer SPC may be positioned inside the third opening OPN3 of the first sub-pixel SPX1 and the third sub-pixel SPX3, or may be positioned inside the third opening OPN3 of the second sub-pixel SPX2 and the third sub-pixel SPX3.

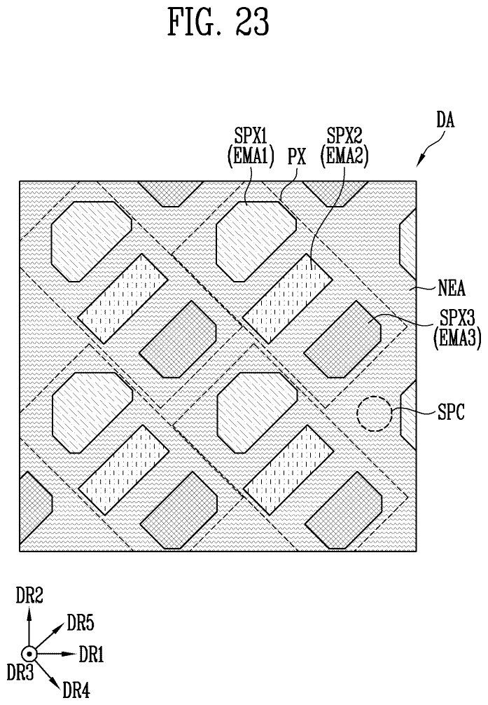

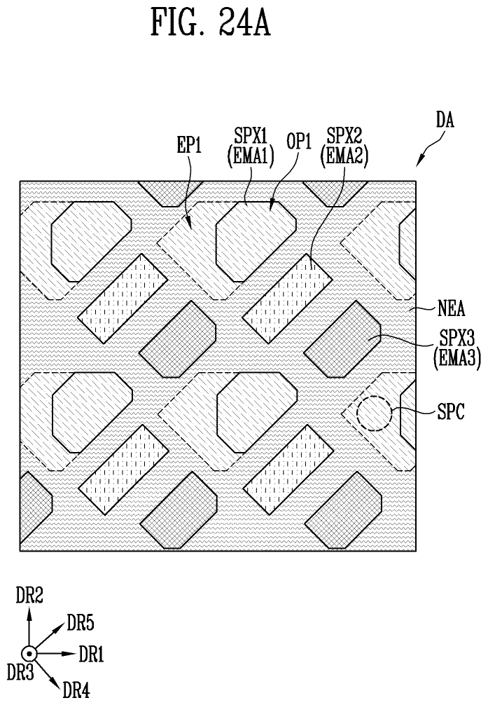

FIG. 23 is an embodiment in which the sub-pixels SPX1, SPX2, and SPX3 may be disposed in the display area DA.

The respective first to third sub-pixels SPX1, SPX2, and SPX3 may correspond to the first to third emission areas EMA1, EMA2, and EMA3. A pixel (e.g., single pixel) PX may include the first to third sub-pixels SPX1, SPX2, and SPX3. In an embodiment, a shape of the pixel PX may entirely have a quadrangular shape. For example, the pixel PX may have a quadrangular shape having a long side extending in the fourth direction DR4 and a short side extending in the fifth direction DR5.

Referring to FIG. 23, the first sub-pixel SPX1 may entirely have a triangular shape, and may have an octagonal shape in which a portion of an area corresponding to each vertex of a triangle may be removed. Each of sides of an octagon may extend in a direction corresponding to one of the first direction DR1, the second direction DR2, the fourth direction DR4, and the fifth direction DR5. However, embodiments of the disclosure are not limited thereto. A shape of the first sub-pixel SPX1 may be configured differently from this.

The second sub-pixel SPX2 may entirely have a quadrangular shape. For example, the second sub-pixel SPX2 may have a quadrangular shape having a long side extending in the fifth direction DR5 and a short side extending in the fourth direction DR4. However, embodiments of the disclosure are not limited thereto. A shape of the second sub-pixel SPX2 may be configured differently from this.

The third sub-pixel SPX3 may entirely have a quadrangular shape, and may have a hexagonal shape in which a portion of an area corresponding to two adjacent vertices of a quadrangle (for example, two vertices positioned in the fourth direction DR4 among four vertices of the quadrangle) may be removed. For example, each of sides of a hexagon may extend in a direction corresponding to one of the second direction DR2, the fourth direction DR4, and the fifth direction DR5. However, embodiments of the disclosure are not limited thereto. A shape of the third sub-pixel SPX3 may be configured differently from this.

In the display area DA, an outer area of the sub-pixels SPX1, SPX2, and SPX3 (or an outer area of the emission areas EMA1, EMA2, and EMA3) may be the non-emission area NEA.

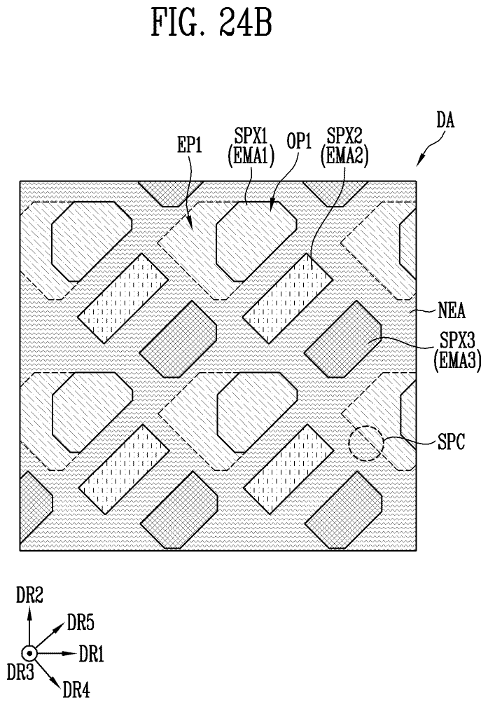

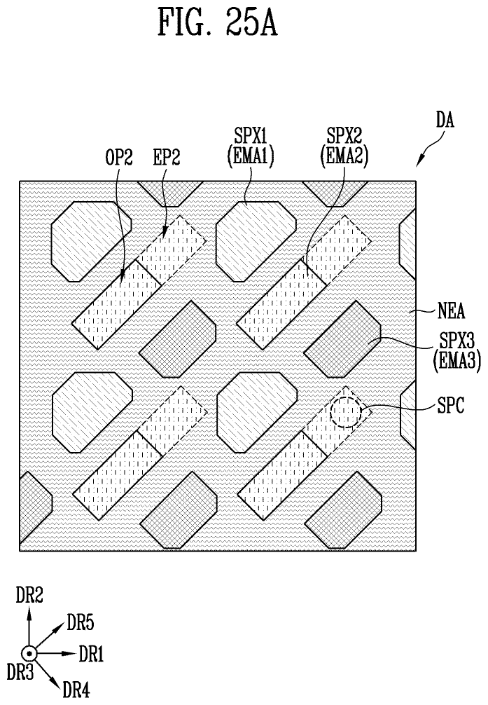

Referring to FIG. 23, the spacer SPC may be disposed outside the pixel PX. For example, the spacer SPC may be disposed in a boundary area between multiple pixels PX. FIGS. 24A to 26B are modified examples of FIG. 23.

Referring to FIGS. 24A to 26B, original areas OP1, OP2, and OP3 and expansion areas EP1, EP2, and EP3 thereof of the respective first to third sub-pixels SPX1, SPX2, and SPX3 are shown.

The first sub-pixel SPX1 may include a first original area OP1 and/or a first expansion area EP1. The second sub-pixel SPX2 may include a second original area OP2 and/or a second expansion area EP2. The third sub-pixel SPX3 may include a third original area OP3 and/or a third expansion area EP3.

The original areas OP1, OP2, and OP3 may correspond to the emission areas EMA1, EMA2, and EMA3 of FIG. 23.

The first expansion area EP1 may correspond to an area where at least one of the first to third openings OPN1, OPN2, and OPN3 of the first sub-pixel SPX1 described above with reference to FIG. 4 or the like may be expanded. The second expansion area EP2 may correspond to an area where at least one of the first to third openings OPN1, OPN2, and OPN3 of the second sub-pixel SPX2 may be expanded. The third expansion area EP3 may correspond to an area where at least one of the first to third openings OPN1, OPN2, and OPN3 of the third sub-pixel SPX3 may be expanded.

In an embodiment, the first expansion area EP1 may be included in the first emission area EMA1, but embodiments of the disclosure are not limited thereto. For example, the first expansion area EP1 may be included in the non-emission area NEA. Similarly, the second expansion area EP2 may be included in the second emission area EMA2 or may be included in the non-emission area NEA. The third expansion area EP3 may be included in the third emission area EMA3 or may be included in the non-emission area NEA. Referring to FIG. 24A, the first expansion area EP1 may extend from the first original area OP1. For example, the first sub-pixel SPX1 or the first emission area EMA1 may entirely have a triangular shape, and may have a heptagonal shape in which a portion of an area corresponding to each of vertices of a triangle may be removed. For example, each of sides of a heptagon may extend in a direction corresponding to one of the first direction DR1, the second direction DR2, the fourth direction DR4, and the fifth direction DR5.

Referring to FIG. 24A, the spacer SPC may be positioned inside the first expansion area EP1. However, embodiments of the disclosure are not limited thereto, and at least a portion of the spacer SPC may be positioned inside the first original area OP1.

Referring to FIG. 24B, at least a portion of the spacer SPC may be positioned inside the first emission area EMA1. For example, referring to FIG. 24B, at least a portion of the spacer SPC may be positioned inside the first expansion area EP1. In an embodiment, at least a portion of the spacer SPC may be positioned inside the first original area OP1.

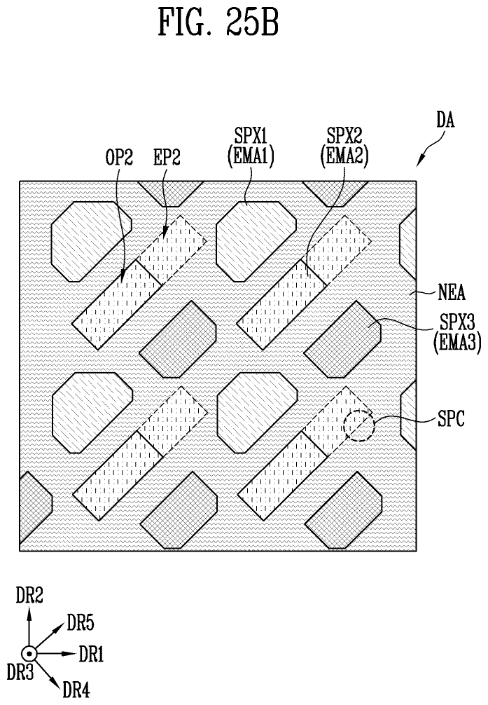

Referring to FIG. 25A, the second expansion area EP2 may extend from the second original area OP2. For example, the second sub-pixel SPX2 or the second emission area EMA2 may entirely have a quadrangular shape. For example, a quadrangle may have a long side extending in the fifth direction DR5 and a short side extending in the fourth direction DR4.

Referring to FIG. 25A, the spacer SPC may be positioned inside the second expansion area EP2. However, embodiments of the disclosure are not limited thereto, and at least a portion of the spacer SPC may be positioned inside the second original area OP2.

Referring to FIG. 25B, at least a portion of the spacer SPC may be positioned inside the second expansion area EP2, and at least a portion of the spacer SPC may be positioned inside the non-emission area NEA.

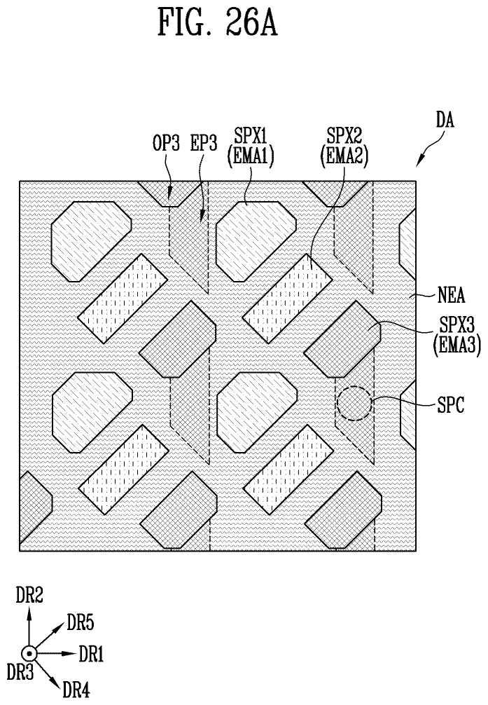

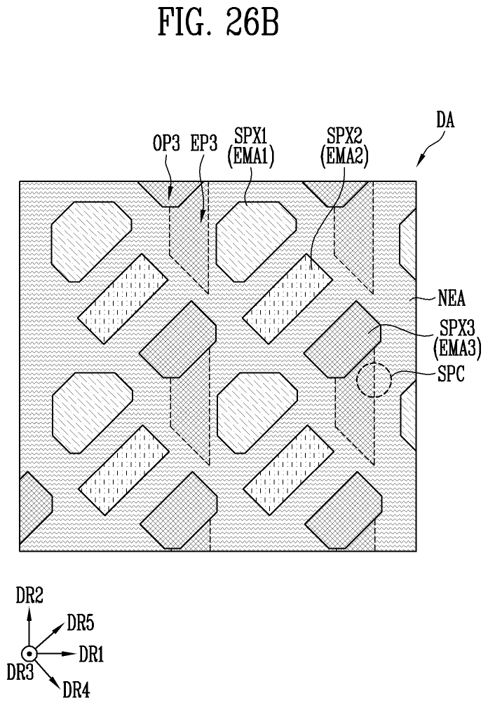

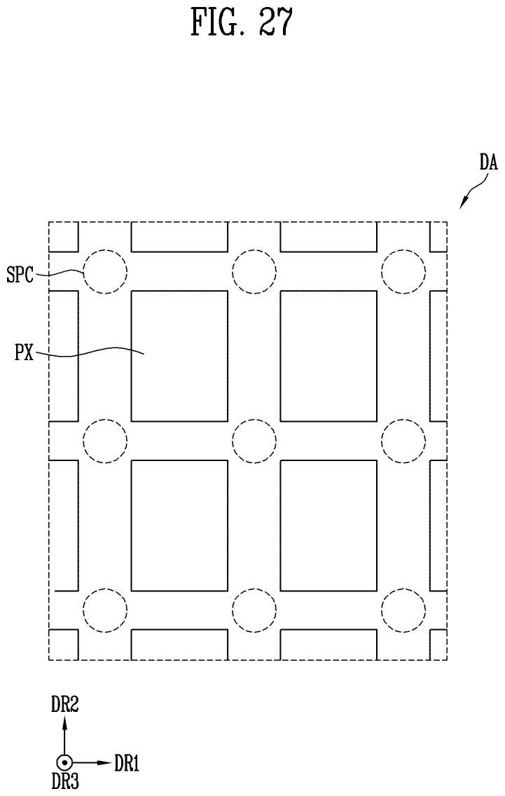

Referring to FIG. 26A, the third expansion area EP3 may extend from the third original area OP3. For example, the third sub-pixel SPX3 or the third emission area EMA3 may have a nonagonal shape. For example, each of sides of a nonagon may extend in a direction corresponding to one of the first direction DR1, the second direction DR2, the fourth direction DR4, and the fifth direction DR5.

Referring to FIG. 26A, the spacer SPC may be positioned inside the third expansion area EP3. However, embodiments of the disclosure are not limited thereto, and at least a portion of the spacer SPC may be positioned inside the third original area OP3.

Referring to FIG. 26B, at least a portion of the spacer SPC may be positioned inside the third expansion area EP3, and a remaining portion may be positioned inside the non-emission area NEA.

FIGS. 27 to 29 are schematic cross-sectional views of an embodiment of the display area DA.

Referring to FIGS. 27 to 29, multiple pixels PX may be disposed in the display area DA. The pixels PX may be disposed side by side in the first and second directions DR1 and DR2, respectively.

The pixel PX may entirely have a quadrangular shape. For example, the pixel PX may have a quadrangular shape having a short side extending in the first direction DR1 and a long side extending in the second direction DR2. However, embodiments of the disclosure are not limited thereto. For example, the pixel PX may have a quadrangular shape having a long side extending in the first direction DR1 and a short side extending in the second direction DR2.

Referring to FIG. 27, the spacer SPC may be placed outside the pixel PX.

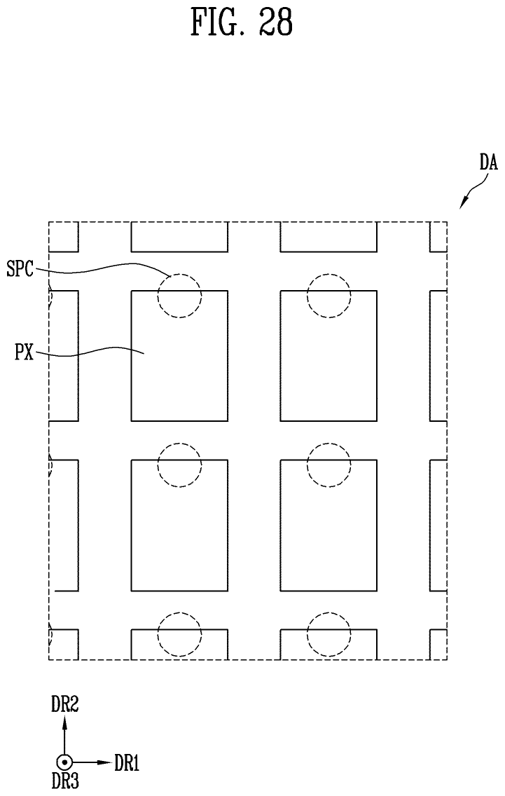

Referring to FIG. 28, at least a portion of the spacer SPC may be disposed to overlap the pixel PX, and a remaining portion of the spacer SPC may be disposed outside the pixel PX.

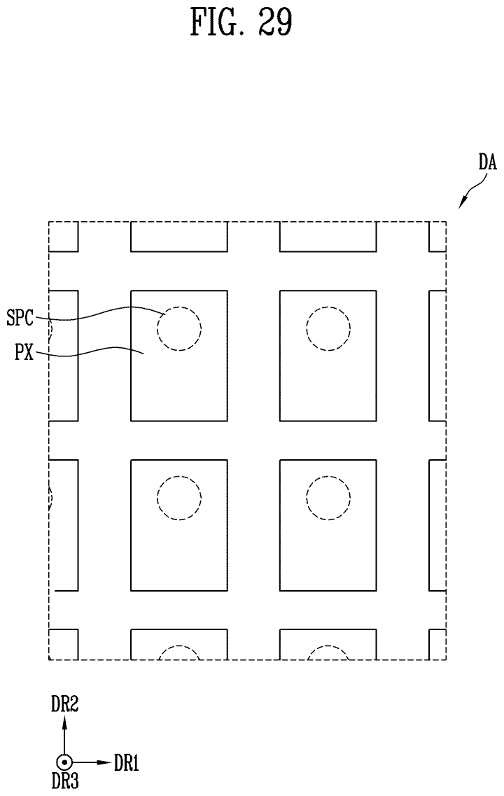

Referring to FIG. 29, the spacer SPC may overlap the pixel PX or may be disposed inside the pixel PX.

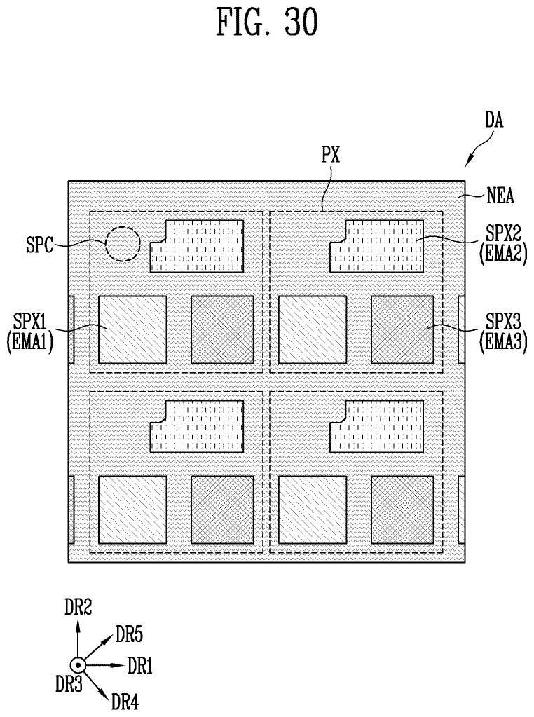

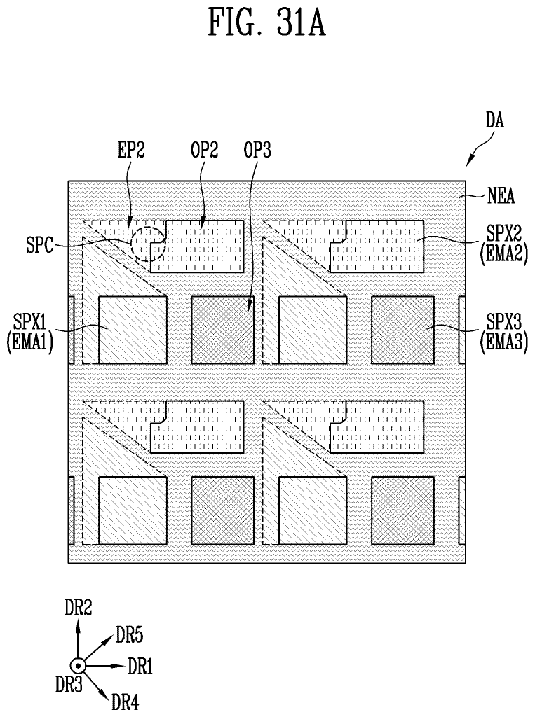

FIG. 30 is an embodiment in which the sub-pixels SPX1, SPX2, and SPX3 may be disposed in the display area DA.

The respective first to third sub-pixels SPX1, SPX2, and SPX3 may correspond to the first to third emission areas EMA1, EMA2, and EMA3. A pixel (e.g., single pixel) PX may include the first to third sub-pixels SPX1, SPX2, and SPX3. In an embodiment, a shape of the pixel PX may entirely have a quadrangular shape.

Referring to FIG. 30, the first sub-pixel SPX1 may entirely have a quadrangular shape. For example, the first sub-pixel SPX1 may have a quadrangular shape having a side (e.g., single side) extending in the first direction DR1 and another side extending in the second direction DR2. However, embodiments of the disclosure are not limited thereto. A shape of the first sub-pixel SPX1 may be configured differently from this.

The second sub-pixel SPX2 may entirely have a quadrangular shape, and may have a heptagonal shape in which a portion of an area corresponding to a vertex (e.g., single vertex) of a quadrangle may be removed. Each of sides of a heptagon may extend in a direction corresponding to one of the first direction DR1, the second direction DR2, and the fifth direction DR5. However, embodiments of the disclosure are not limited thereto. A shape of the second sub-pixel SPX2 may be configured differently from this.

The third sub-pixel SPX3 may entirely have a quadrangular shape. For example, the third sub-pixel SPX3 may have a quadrangular shape in which a side (e.g., single side) may extend in the first direction DR1 and another side may extend in the second direction DR2. However, embodiments of the disclosure are not limited thereto. A shape of the third sub-pixel SPX3 may be configured differently from this.

Referring to FIG. 30, the spacer SPC may be disposed outside the sub-pixels SPX1, SPX2, and SPX3 in the pixel PX.

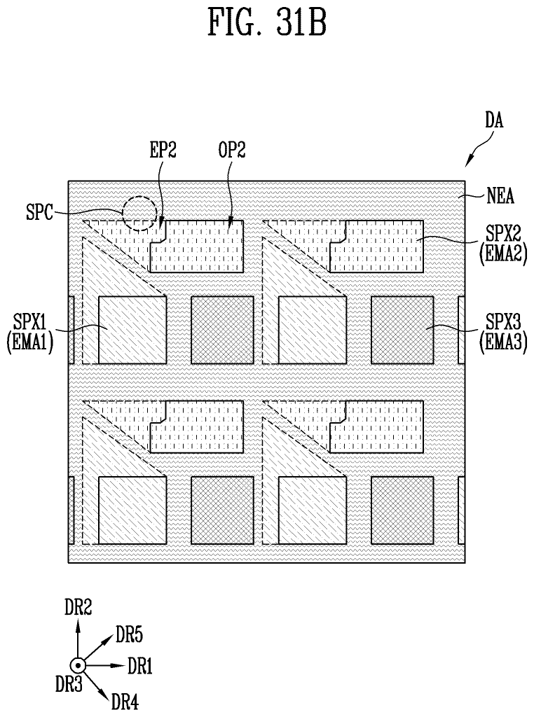

FIGS. 31A to 35 are modified embodiments of FIG. 30.

Referring to FIGS. 31A to 35, the original areas OP1, OP2, and OP3 of the respective first to third sub-pixels SPX1, SPX2, and SPX3 and the expansion areas EP1 and EP2 of the first and second sub-pixels SPX1 and SPX2 are shown.

The original areas OP1, OP2, and OP3 may correspond to the emission areas EMA1, EMA2, and EMA3 of FIG. 30.

The first expansion area EP1 may correspond to an area where at least one of the first to third openings OPN1, OPN2, and OPN3 of the first sub-pixel SPX1 described above with reference to FIG. 4 or the like may be expanded. The second expansion area EP2 may correspond to an area where at least one of the first to third openings OPN1, OPN2, and OPN3 of the second sub-pixel SPX2 may be expanded.

In an embodiment, the first expansion area EP1 may be included in the first emission area EMA1, but embodiments of the disclosure are not limited thereto. For example, the first expansion area EP1 may be included in the non-emission area NEA. Similarly, the second expansion area EP2 may be included in the second emission area EMA2 or may be included in the non-emission area NEA.

The first expansion area EP1 may extend from the first original area OP1. For example, the first sub-pixel SPX1 or the first emission area EMA1 may entirely have a quadrangular (for example, trapezoidal) shape. For example, each of sides of a quadrangle may extend in a direction corresponding to one of the first direction DR1, the second direction DR2, and the fourth direction DR4.

The second expansion area EP2 may extend from the second original area OP2. For example, the second sub-pixel SPX2 or the second emission area EMA2 may entirely have a quadrangular (for example, trapezoidal) shape. For example, each of sides of a quadrangle may extend in a direction corresponding to one of the first direction DR1, the second direction DR2, and the fourth direction DR4.

Referring to FIG. 31A, at least a portion of the spacer SPC may be positioned inside the second expansion area EP2. A remaining portion of the spacer SPC may be positioned inside the second original area OP2.

Referring to FIG. 31B, at least a portion of the spacer SPC may be positioned inside the second expansion area EP2, and a remaining portion of the spacer SPC may be positioned outside the second expansion area EP2. In an embodiment, the remaining portion of the spacer SPC may be positioned inside the second original area OP2.

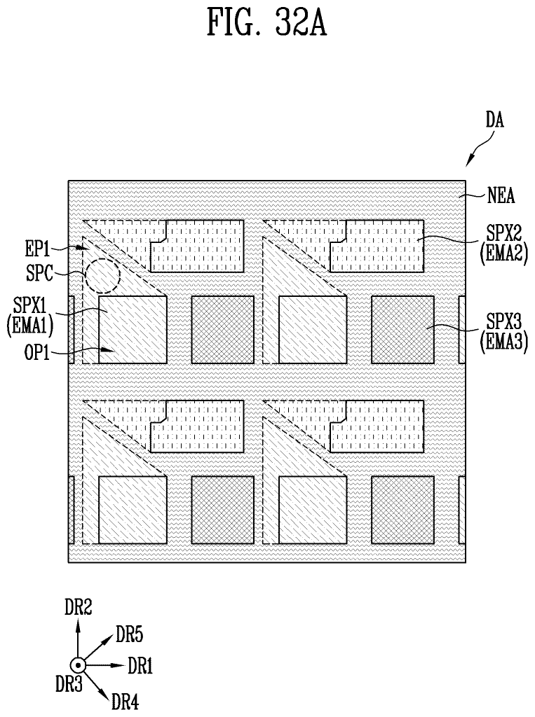

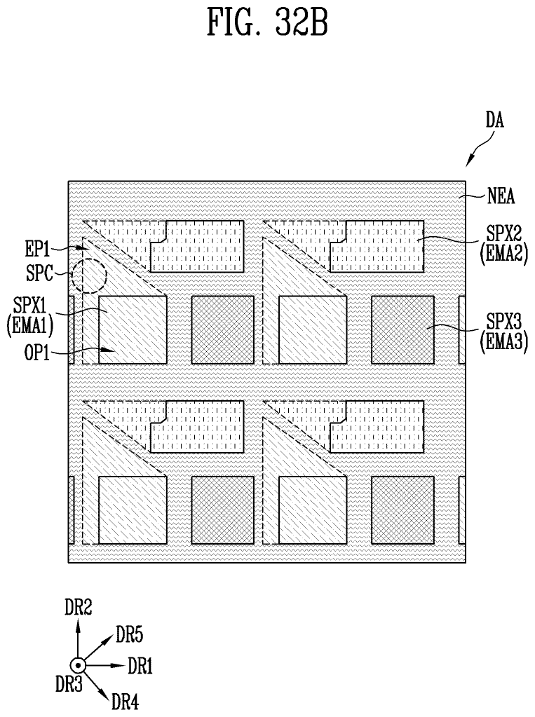

Referring to FIG. 32A, the spacer SPC may be positioned inside the first expansion area EP1. However, embodiments of the disclosure are not limited thereto, and at least a portion of the spacer SPC may be positioned inside the first original area OP1.

Referring to FIG. 32B, at least a portion of the spacer SPC may be positioned inside the first expansion area EP1, and a remaining portion of the spacer SPC may be positioned outside the first expansion area EP1. In an embodiment, the remaining portion of the spacer SPC may be positioned inside the first original area OP1.

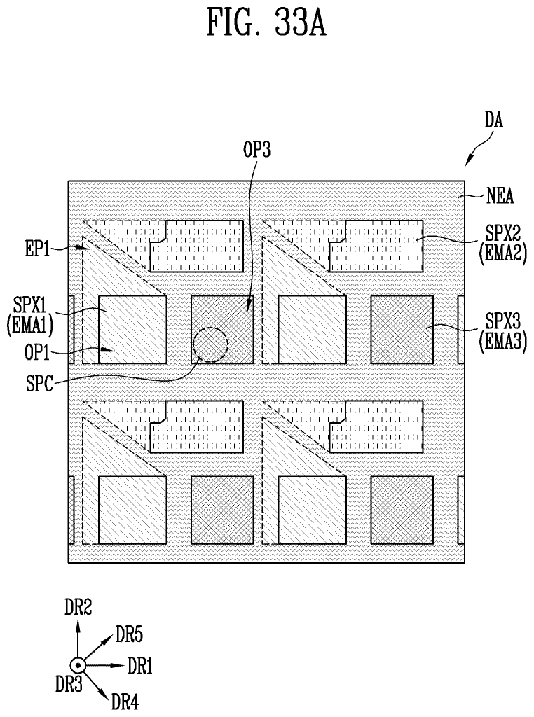

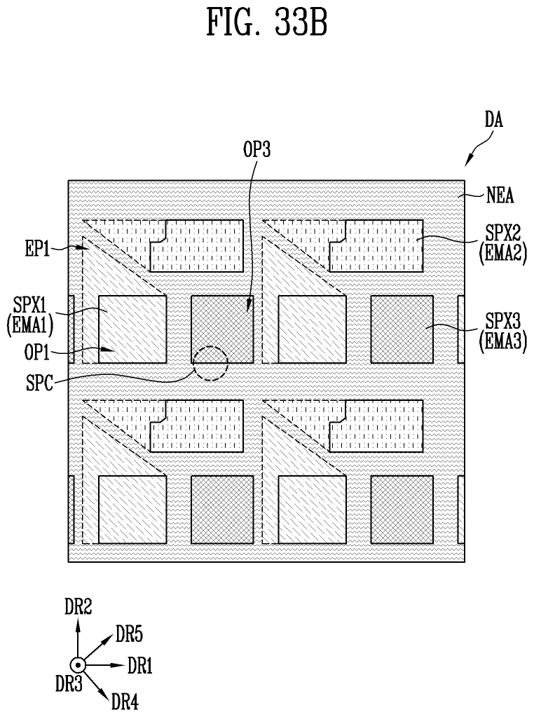

Referring to FIG. 33A, the spacer SPC may be positioned inside the third emission area EMA3 (or to entirely overlap the third emission area EMA3). For example, referring to FIG. 33A, the spacer SPC may be positioned inside the third original area OP3.

Referring to FIG. 33B, at least a portion of the spacer SPC may be positioned inside the third emission area EMA3. For example, referring to FIG. 33B, at least a portion of the spacer SPC may be positioned inside the third original area OP3, and a remaining portion of the spacer SPC may be positioned in the non-emission area NEA.

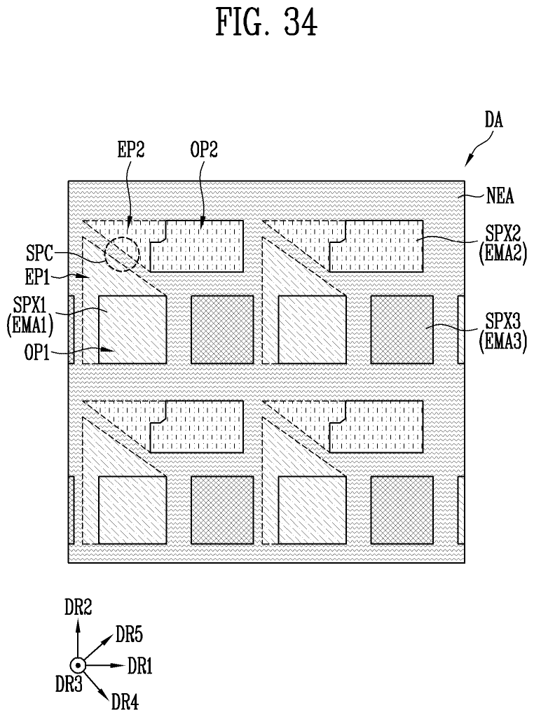

Referring to FIG. 34, the spacer SPC may overlap the first and second expansion areas EP1 and EP2.

Referring to FIG. 34, at least a portion of the spacer SPC may be positioned inside the first expansion area EP1, and at least a portion of the spacer SPC may be positioned inside the second expansion area EP2. A remaining portion of the spacer SPC may be positioned outside the first and second expansion areas EP1 and EP2 (for example, the non-emission area NEA). However, embodiments of the disclosure are not limited thereto. For example, at least a portion of the spacer SPC may be positioned inside the first original area OP1. At least a portion of the spacer SPC may be positioned inside the second original area OP2.

In an embodiment, the spacer SPC may overlap the first and third sub-pixels SPX1 and SPX3, or may overlap the second and third sub-pixels SPX2 and SPX3.

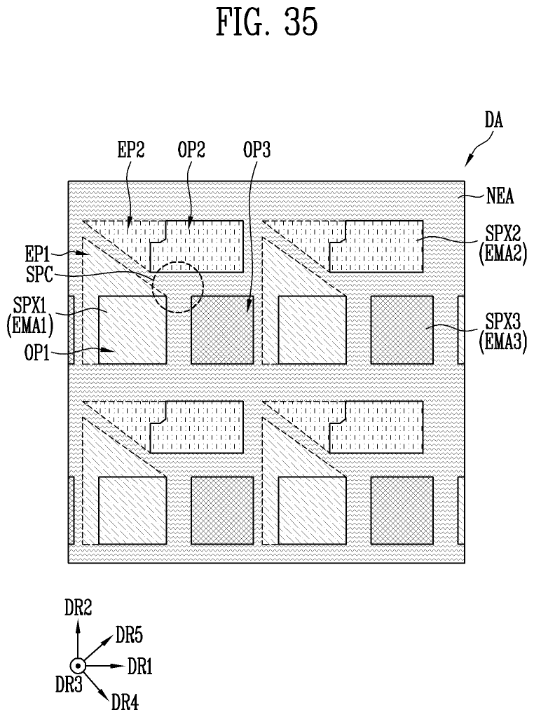

Referring to FIG. 35, the spacer SPC may overlap the first to third sub-pixels SPX1 to SPX3.

In the above embodiment, at least a portion of the spacer SPC may be positioned inside the first emission area EMA1, at least a portion of a remainder of may be positioned inside the second emission area EMA2, and at least a portion of the remainder may be positioned inside the third emission area EMA3. For example, referring to FIG. 35, at least a portion of the spacer SPC may be positioned inside the first expansion area EP1, at least a portion may be positioned inside the first original area OP1, at least a portion may be positioned inside the second original area OP2, and at least a portion may be positioned inside the third original area OP3. However, embodiments of the disclosure are not limited thereto. For example, at least a portion of the spacer SPC may be positioned inside the second expansion area EP2.

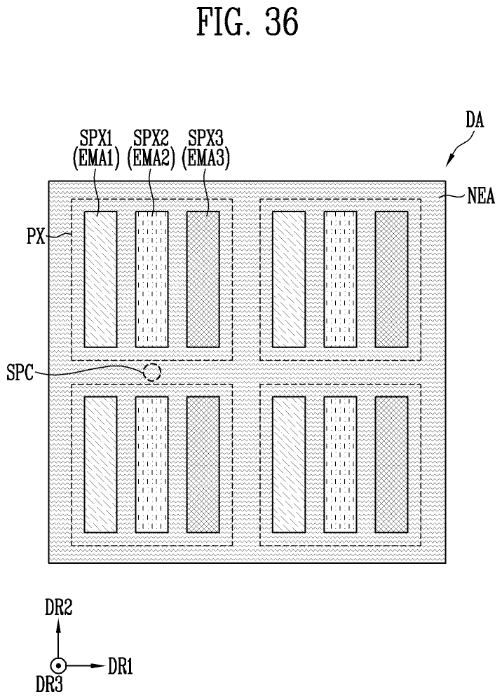

FIG. 36 is still an embodiment in which the sub-pixels SPX1, SPX2, and SPX3 are disposed in the display area DA.

The respective first to third sub-pixels SPX1, SPX2, and SPX3 may correspond to the first to third emission areas EMA1, EMA2, and EMA3. A pixel (e.g., single pixel) PX may include the first to third sub-pixels SPX1, SPX2, and SPX3. In an embodiment, a shape of the pixel PX may entirely have a quadrangular shape.

Referring to FIG. 36, the first sub-pixel SPX1 may entirely have a quadrangular shape. For example, the first sub-pixel SPX1 may have a quadrangular shape having a side (for example, a short side) extending in the first direction DR1 and another side (for example, a long side) extending in the second direction DR2. However, embodiments of the disclosure are not limited thereto. A shape of the first sub-pixel SPX1 may be configured differently from this. The second sub-pixel SPX2 may entirely have a quadrangular shape. For example, the second sub-pixel SPX2 may have a quadrangular shape having a side (for example, a short side) extending in the first direction DR1 and another side (for example, a long side) extending in the second direction DR2. However, embodiments of the disclosure are not limited thereto. A shape of the second sub-pixel SPX2 may be configured differently from this.

The third sub-pixel SPX3 may entirely have a quadrangular shape. For example, the third sub-pixel SPX3 may have a quadrangular shape having a side (for example, a short side) extending in the first direction DR1 and another side (for example, a long side) extending in the second direction DR2. However, embodiments of the disclosure are not limited thereto. A shape of the third sub-pixel SPX3 may be configured differently from this.

Referring to FIG. 36, the spacer SPC may be disposed outside the pixel PX.

However, embodiments of the disclosure are not limited thereto. For example, the spacer SPC may be disposed inside the pixel PX, and may be disposed outside the sub-pixels SPX1, SPX2, and SPX3. For example, the spacer SPC may be disposed to overlap at least a portion of the sub-pixels SPX1, SPX2, and SPX3.

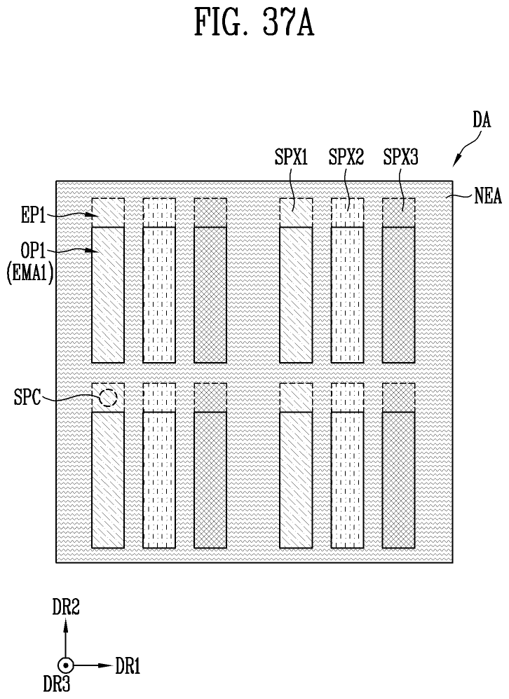

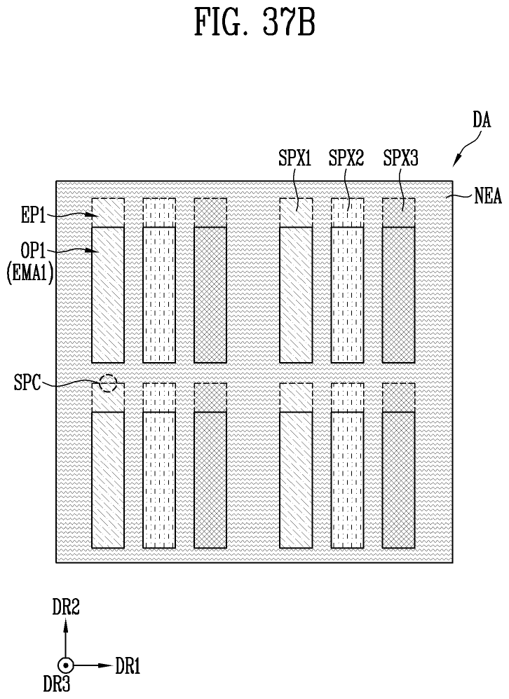

FIGS. 37A to 52 are modified embodiments of FIG. 36.

Referring to FIGS. 37A to 42, original areas OP1, OP2, OP3 of each of the first to third sub-pixels SPX1, SPX2, and SPX3 and the expansion areas EP1, EP2, and EP3 of the first to third sub-pixels SPX1, SPX2, SPX3 is shown.

The first sub-pixel SPX1 may include the first original area OP1 and the first expansion area EP1. The second sub-pixel SPX2 may include the second original area OP2 and the second expansion area EP2. The third sub-pixel SPX3 may include the third original area OP3 and the third expansion area EP3.

The original areas OP1, OP2, and OP3 may correspond to the emission areas EMA1, EMA2, and EMA3 of FIG. 36.

The first expansion area EP1 may correspond to an area where at least one of the first to third openings OPN1, OPN2, and OPN3 of the first sub-pixel SPX1 described above with reference to FIG. 4 or the like may be expanded. The second expansion area EP2 may correspond to an area where at least one of the first to third openings OPN1, OPN2, and OPN3 of the second sub-pixel SPX2 may be expanded. The third expansion area EP3 may correspond to an area where at least one of the first to third openings OPN1, OPN2, and OPN3 of the third sub-pixel SPX3 may be expanded.

In an embodiment, the first expansion area EP1 may be included in the first emission area EMA1, but embodiments of the disclosure are not limited thereto. For example, the first expansion area EP1 may be included in the non-emission area NEA. Similarly, the second expansion area EP2 may be included in the second emission area EMA2 or may be included in the non-emission area NEA. The third expansion area EP3 may be included in the third emission area EMA3 or may be included in the non-emission area NEA.

Referring to FIGS. 37A to 42, a shape of the first to third expansion areas EP1, EP2, and EP3 as follows as an example.

The first expansion area EP1 may extend from the first original area OP1. For example, the first sub-pixel SPX1 or the first emission area EMA1 may entirely have a quadrangular (for example, rectangular) shape. For example, each of sides of a quadrangle may extend in a direction corresponding to one of the first direction DR1 and the second direction DR2.

The second expansion area EP2 may extend from the second original area OP2. For example, the second sub-pixel SPX2 or the second emission area EMA2 may entirely have a quadrangular (for example, rectangular) shape. For example, each of sides of a quadrangle may extend in a direction corresponding to one of the first direction DR1 and the second direction DR2.

The third expansion area EP3 may extend from the third original area OP3. For example, the third sub-pixel SPX3 or the third emission area EMA3 may entirely have a quadrangular (for example, rectangular) shape. For example, each of sides of a quadrangle may extend in a direction corresponding to one of the first direction DR1 and the second direction DR2.

Referring to FIG. 37A, the spacer SPC may be positioned inside the first expansion area EP1. However, embodiments of the disclosure are not limited thereto, and at least a portion of the spacer SPC may be positioned inside the first original area OP1.

Referring to FIG. 37B, at least a portion of the spacer SPC may be positioned inside the first expansion area EP1, and a remaining portion of the spacer SPC may be positioned outside the first expansion area EP1. In an embodiment, at least a portion of the spacer SPC may be positioned inside the first original area OP1.

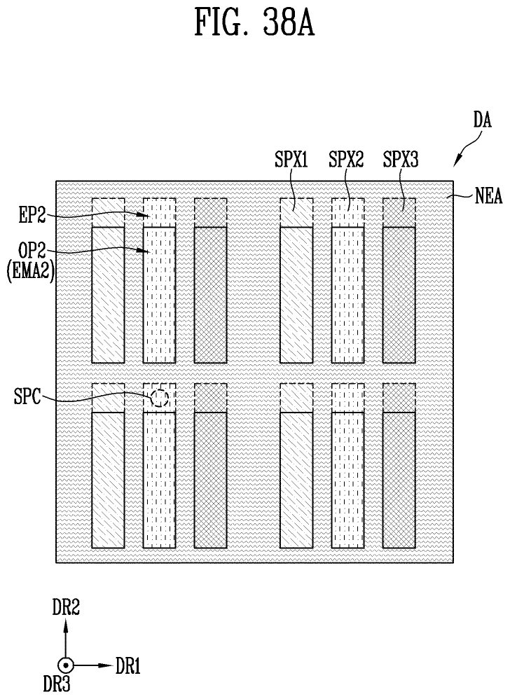

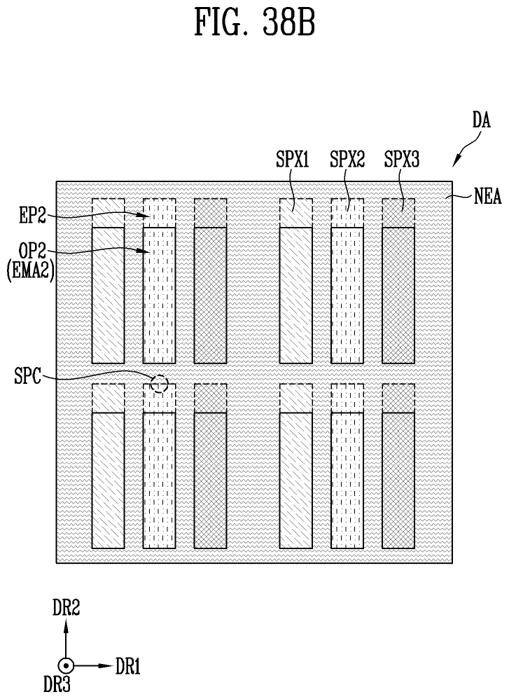

Referring to FIG. 38A, the spacer SPC may be positioned inside the second expansion area EP2. However, embodiments of the disclosure are not limited thereto, and at least a portion of the spacer SPC may be positioned inside the second original area OP2.

Referring to FIG. 38B, at least a portion of the spacer SPC may be positioned inside the second expansion area EP2, and a remaining portion of the spacer SPC may be positioned outside the second expansion area EP2. In an embodiment, at least a portion of the spacer SPC may be positioned inside the second original area OP2.

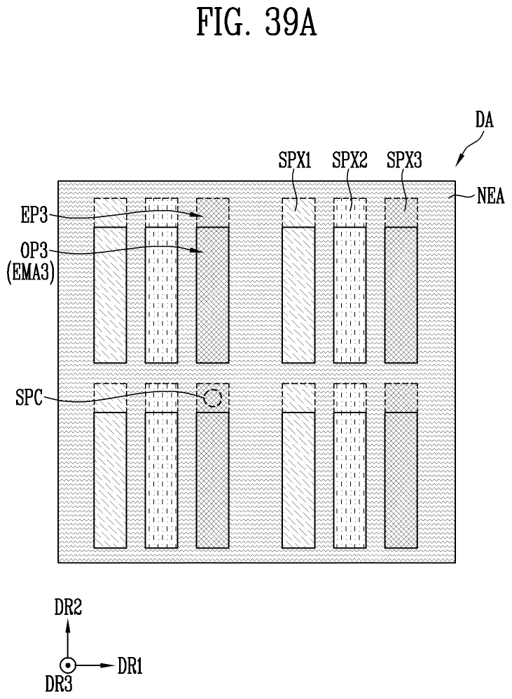

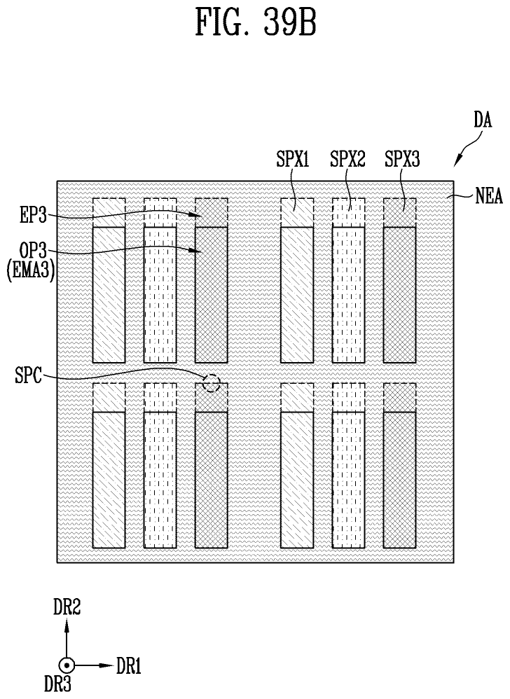

Referring to FIG. 39A, the spacer SPC may be positioned inside the third expansion area EP3. However, embodiments of the disclosure are not limited thereto, and at least a portion of the spacer SPC may be positioned inside the third original area OP3.

Referring to FIG. 39B, at least a portion of the spacer SPC may be positioned inside the third expansion area EP3, and a remaining portion of the spacer SPC may be positioned outside the third expansion area EP3. However, embodiments of the disclosure are not limited thereto, and at least a portion of the spacer SPC may be positioned inside the third original area OP3.

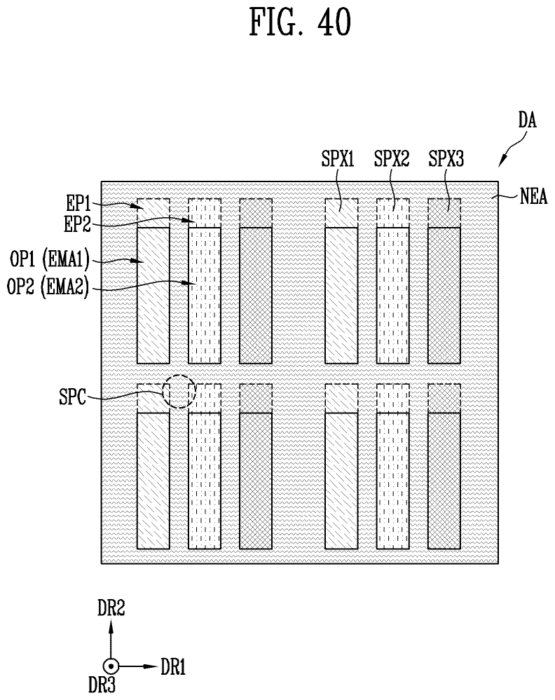

Referring to FIG. 40, the spacer SPC may overlap the first and second sub-pixels SPX1 and SPX2.

Referring to FIG. 40, at least a portion of the spacer SPC may be positioned inside the first expansion area EP1, and at least a portion of the spacer SPC may be positioned inside the second expansion area EP2. A remaining portion of the spacer SPC may be positioned outside the first and second expansion areas EP1 and EP2 (for example, the non-emission area NEA). However, embodiments of the disclosure are not limited thereto. For example, at least a portion of the spacer SPC may be positioned inside the first original area OP1. At least a portion of the spacer SPC may be positioned inside the second original area OP2.

In an embodiment, the spacer SPC may overlap the first and third sub-pixels SPX1 and SPX3, or may overlap the second and third sub-pixels SPX2 and SPX3.

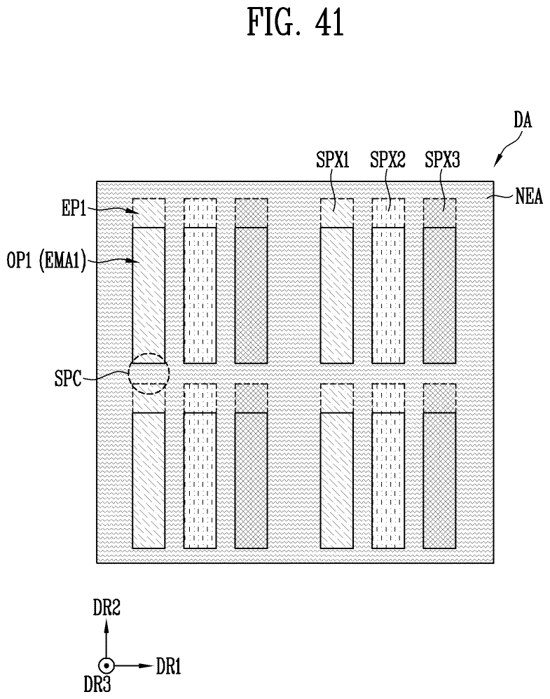

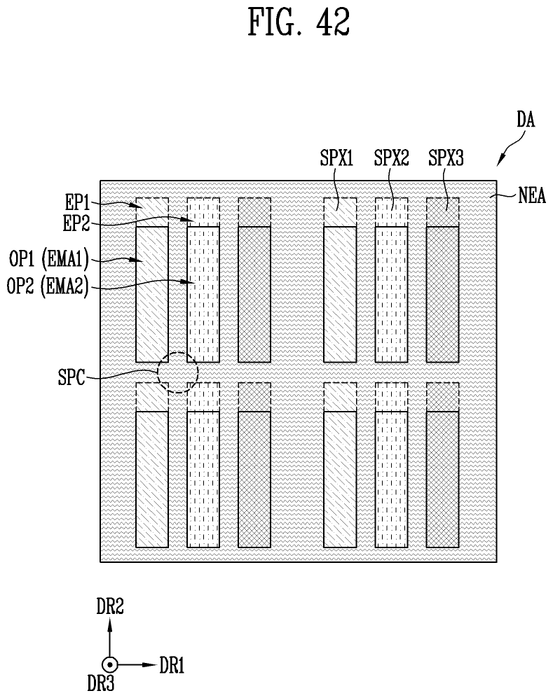

Referring to FIG. 41, the spacer SPC may overlap multiple first sub-pixels SPX1.

Referring to FIG. 41, at least a portion of the spacer SPC may be positioned inside the first original area OP1 of the first sub-pixel SPX1 positioned on a side (for example, an upper side), and at least a portion of the spacer SPC may be positioned inside the first expansion area EP1 of the first sub-pixel SPX1 positioned on another side (for example, a lower side). A remaining portion of the spacer SPC may be positioned in the non-emission area NEA positioned between the original area OP1 and the expansion area EP1 adjacent in the second direction DR2. However, embodiments of the disclosure are not limited thereto. In an embodiment, the spacer SPC may overlap multiple second sub-pixels SPX2, or may overlap multiple third sub-pixels SPX3.

Referring to FIG. 42, the spacer SPC may overlap the first sub-pixels SPX1 and the second sub-pixels SPX2.

Referring to FIG. 42, at least a portion of the spacer SPC may be positioned inside the first original area OP1 of the first sub-pixel SPX1 positioned on a side (for example, the upper side), and at least a portion of the spacer SPC may be positioned inside the first expansion area EP1 of the first sub-pixel SPX1 positioned on another side (for example, the lower side). At least a portion of the spacer SPC may be positioned inside the second original area OP2 of the second sub-pixel SPX2 positioned on a side (for example, the upper side), and at least a portion of the spacer SPC may be positioned inside the second expansion area EP2 of the second sub-pixel SPX2 positioned on another side (for example, the lower side). A remaining portion of the spacer SPC may be positioned in the non-emission area NEA positioned between the first sub-pixels SPX1 and the second sub-pixels SPX2 adjacent to each other in the second direction DR2. However, embodiments of the disclosure are not limited thereto. In an embodiment, the spacer SPC may overlap the first sub-pixels SPX1 and the third sub-pixels SPX3. In an embodiment, the spacer SPC may overlap the second sub-pixels SPX2 and the third sub-pixels SPX3.

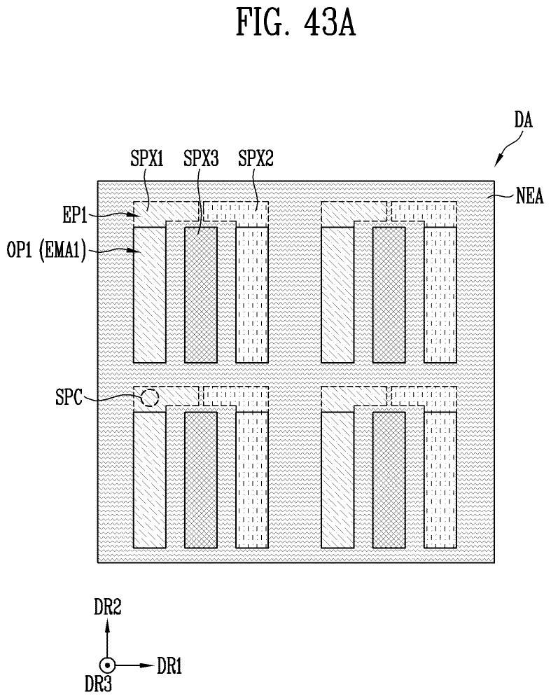

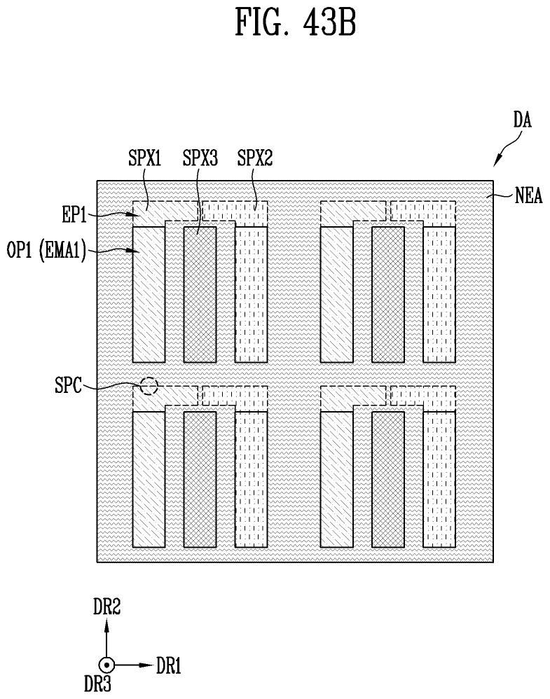

Referring to FIGS. 43A to 52, the original areas OP1, OP2, and OP3 of the respective first to third sub-pixels SPX1, SPX2, and SPX3 and the expansion areas EP1 and EP2 of the respective first and second sub-pixels SPX1 and SPX2 are shown.

Referring to FIGS. 43A to 47, a shape of the first and second expansion areas EP1 and EP2 as follows is described as an example.

The first expansion area EP1 may extend from the first original area OP1. For example, the first expansion area EP1 may sequentially extend from the first original area OP1 in the second direction DR2 and the first direction DR1 and may entirely have a “┌” shape. For example, the first sub-pixel SPX1 may entirely have a hexagonal shape. For example, each of sides of a hexagon may extend in a direction corresponding to one of the first direction DR1 and the second direction DR2.

The second expansion area EP2 may extend from the second original area OP2. For example, the second expansion area EP2 may sequentially extend from the first original area OP1 in the second direction DR2 and in a direction opposite to the first direction DR1 and may entirely have a “¬” shape. For example, the second sub-pixel SPX2 may entirely have a hexagonal shape. For example, each of sides of a hexagon may extend in a direction corresponding to one of the first direction DR1 and the second direction DR2.

The first expansion area EP1 and the second expansion area EP2 may be adjacent to each other in the first direction DR1. Each of the first expansion area EP1 and the second expansion area EP2 may be positioned in the second direction DR2 from the third original area OP3.

Referring to FIG. 43A, the spacer SPC may be positioned inside the first expansion area EP1. However, embodiments of the disclosure are not limited thereto, and at least a portion of the spacer SPC may be positioned inside the first original area OP1.

Referring to FIG. 43B, at least a portion of the spacer SPC may be positioned inside the first expansion area EP1, and a remaining portion of the spacer SPC may be positioned outside the first expansion area EP1. In an embodiment, at least a portion of the spacer SPC may be positioned inside the first original area OP1.

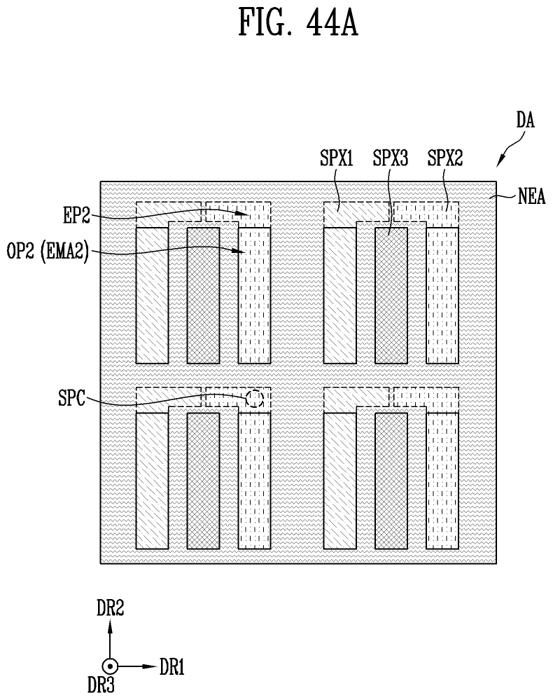

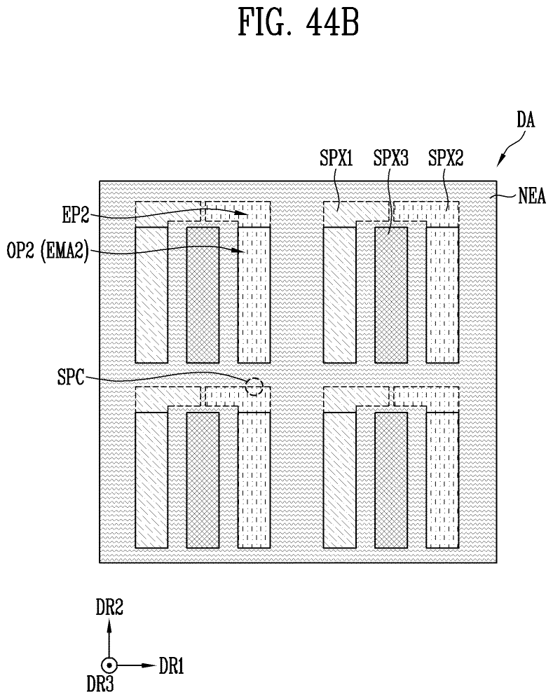

Referring to FIG. 44A, the spacer SPC may be positioned inside the second expansion area EP2. However, embodiments of the disclosure are not limited thereto, and at least a portion of the spacer SPC may be positioned inside the second original area OP2.

Referring to FIG. 44B, at least a portion of the spacer SPC may be positioned inside the second expansion area EP2, and a remaining portion of the spacer SPC may be positioned outside the second expansion area EP2. In an embodiment, at least a portion of the spacer SPC may be positioned inside the second original area OP2.

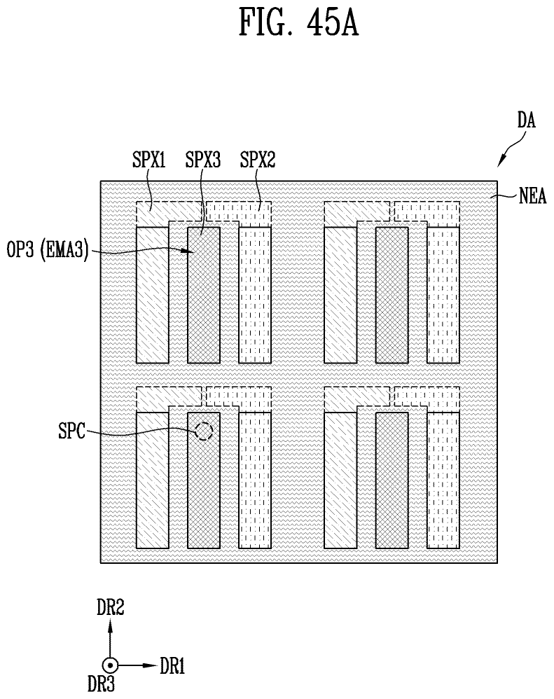

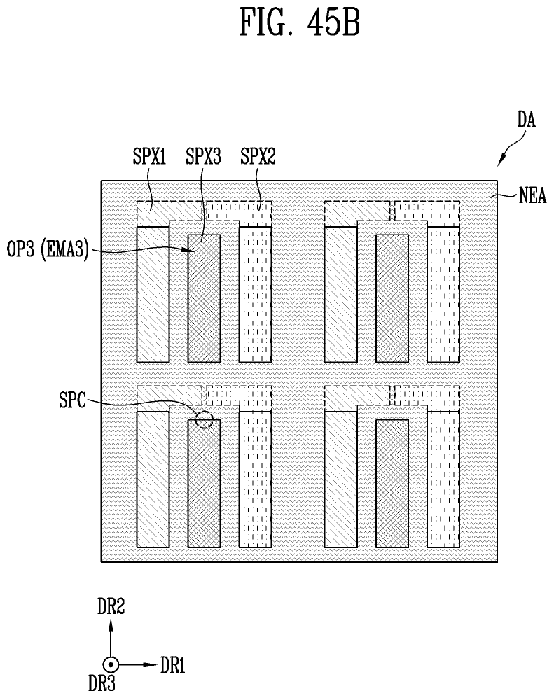

Referring to FIG. 45A, the spacer SPC may be positioned inside the third emission area EMA3 (or to entirely overlap the third emission area EMA3). For example, referring to FIG. 45A, the spacer SPC may be positioned inside the third original area OP3.

Referring to FIG. 45B, at least a portion of the spacer SPC may be positioned inside the third emission area EMA3. For example, referring to FIG. 45B, at least a portion of the spacer SPC may be positioned inside the third original area OP3, and a remaining portion of the spacer SPC may be positioned in the non-emission area NEA.

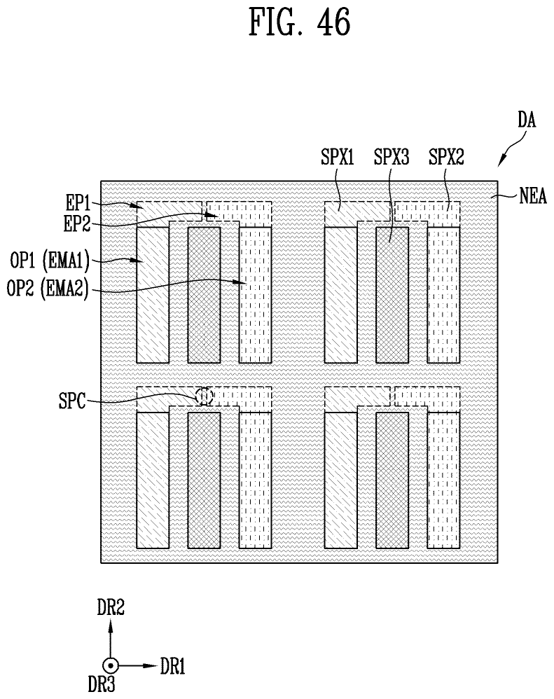

Referring to FIG. 46, the spacer SPC may overlap the first and second sub-pixels SPX1 and SPX2.

Referring to FIG. 46, at least a portion of the spacer SPC may be positioned inside the first expansion area EP1, and at least a portion of the spacer SPC may be positioned inside the second expansion area EP2. A remaining portion of the spacer SPC may be positioned in an area between the first expansion area EP1 and the second expansion area EP2 (for example, the non-emission area NEA). However, embodiments of the disclosure are not limited thereto. For example, at least a portion of the spacer SPC may be positioned inside the first original area OP1. At least a portion of the spacer SPC may be positioned inside the second original area OP2.

In an embodiment, the spacer SPC may overlap the first and third sub-pixels SPX1 and SPX3, or may overlap the second and third sub-pixels SPX2 and SPX3.

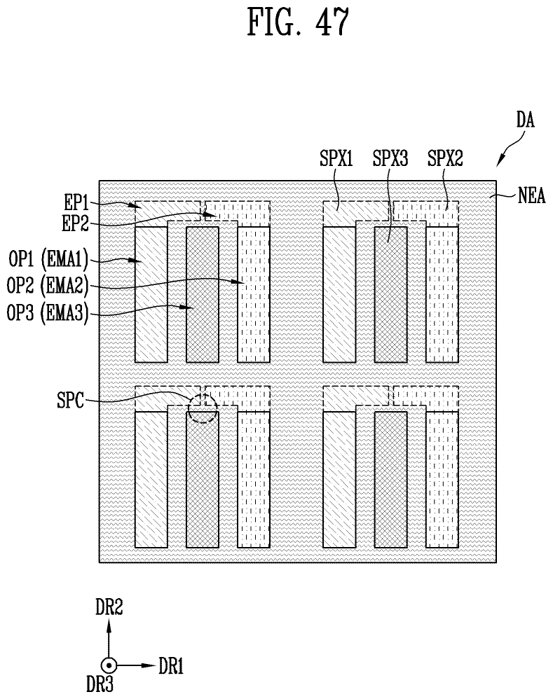

Referring to FIG. 47, the spacer SPC may overlap the first to third sub-pixels SPX1 to SPX3.

Referring to FIG. 47, at least a portion of the spacer SPC may be positioned inside the first expansion area EP1, at least a portion may be positioned inside the second expansion area EP2, and at least a portion may be positioned inside the third original area OP3. However, embodiments of the disclosure are not limited thereto. For example, at least a portion of the spacer SPC may be positioned inside the first original area OP1, or may be positioned inside the second original area OP2.

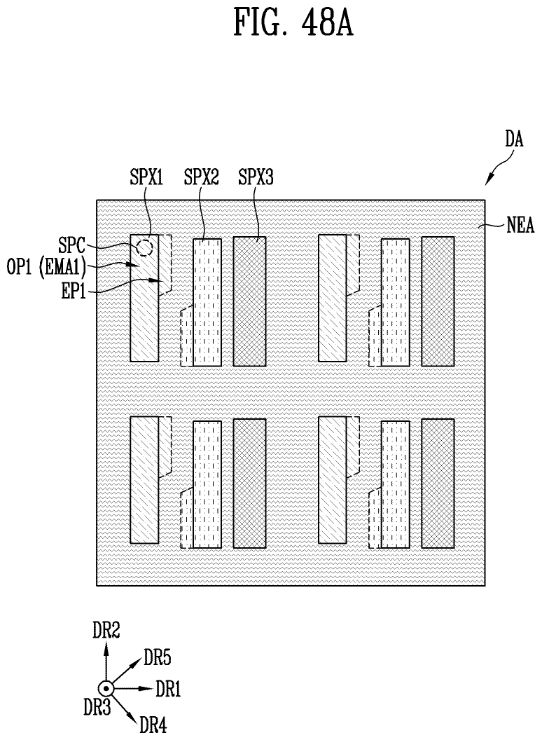

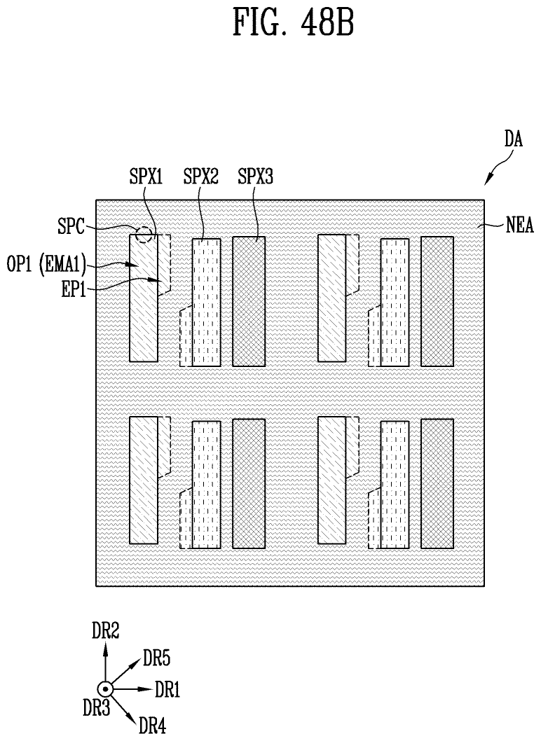

Referring to FIGS. 48A to 52, a shape of the first and second expansion areas EP1 and EP2 as follows is described as an example.

The first expansion area EP1 may extend from the first original area OP1. For example, the first expansion area EP1 may extend from the first original area OP1 in the first direction DR1 while narrowing in width, and may entirely have a shape in which “I” may be inversed in a left-right direction. For example, the first sub-pixel SPX1 may entirely have a hexagonal shape. For example, each of sides of a hexagon may extend in a direction corresponding to one of the first direction DR1, the second direction DR2, and the fifth direction DR5.

The second expansion area EP2 may extend from the second original area OP2. For example, the second expansion area EP2 may extend from the second original area OP2 in a direction opposite to the first direction DR1 while narrowing in width, and may entirely have a shape in which “J” may be inversed upside down. For example, the second sub-pixel SPX2 may entirely have a hexagonal shape. For example, each of sides of a hexagon may extend in a direction corresponding to one of the first direction DR1, the second direction DR2, and the fifth direction DR5.

The first expansion area EP1 and the second expansion area EP2 may be adjacent to each other in the fourth direction DR4.

Referring to FIG. 48A, the spacer SPC may be positioned inside the first original area OP1. However, embodiments of the disclosure are not limited thereto, and at least a portion of the spacer SPC may be positioned inside the first expansion area EP1.

Referring to FIG. 48B, at least a portion of the spacer SPC may be positioned inside the first original area OP1, and a remaining portion of the spacer SPC may be positioned in the non-emission area NEA. However, embodiments of the disclosure are not limited thereto, and at least a portion of the spacer SPC may be positioned inside the first expansion area EP1.

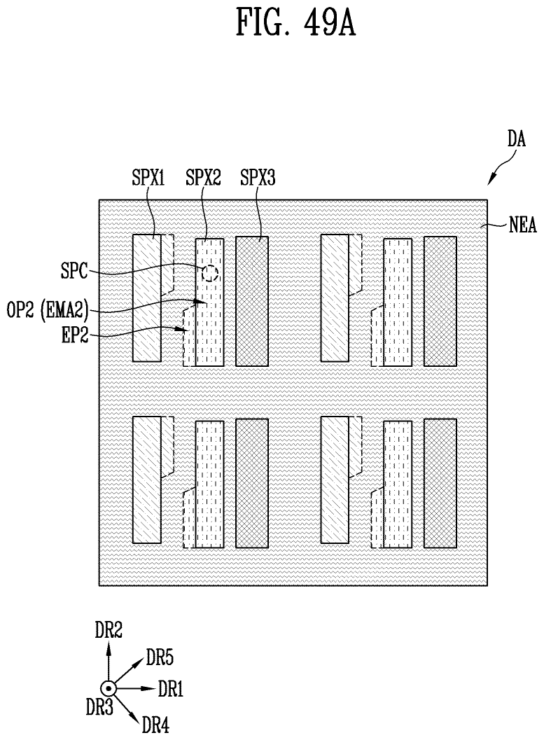

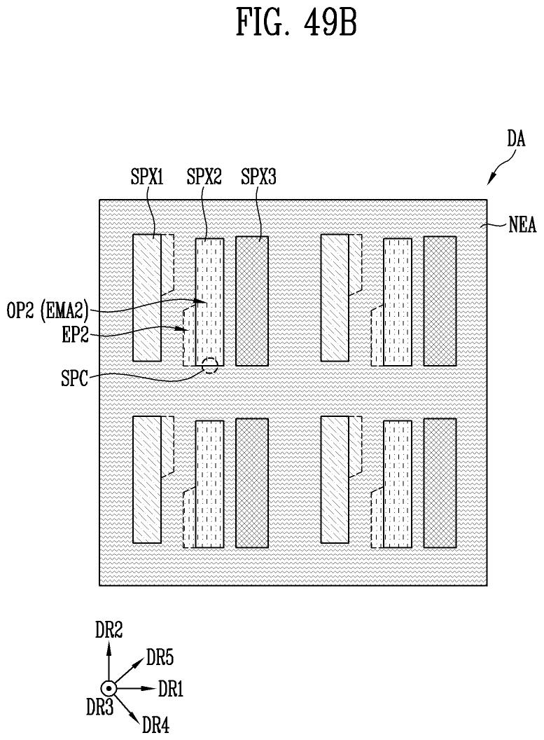

Referring to FIG. 49A, the spacer SPC may be positioned inside the second original area OP2. However, embodiments of the disclosure are not limited thereto, and at least a portion of the spacer SPC may be positioned inside the second expansion area EP2.

Referring to FIG. 49B, at least a portion of the spacer SPC may be positioned inside the second original area OP2, and a remaining portion of the spacer SPC may be positioned in the non-emission area NEA. However, embodiments of the disclosure are not limited thereto, and at least a portion of the spacer SPC may be positioned inside the second expansion area EP2.

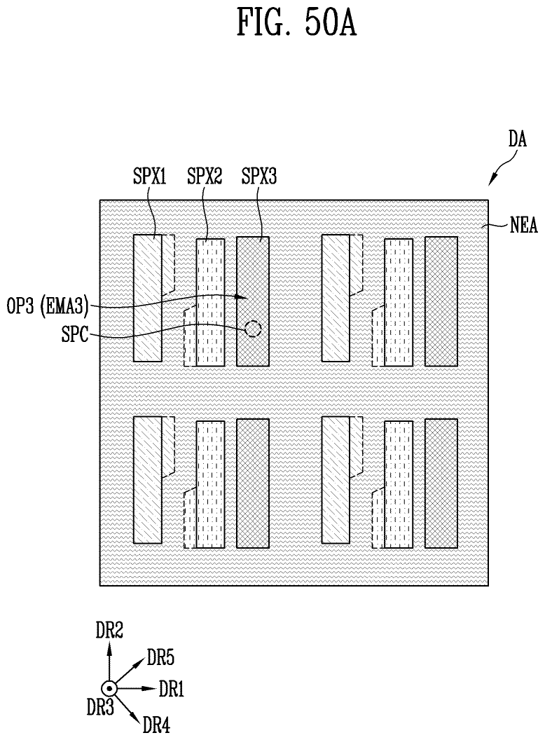

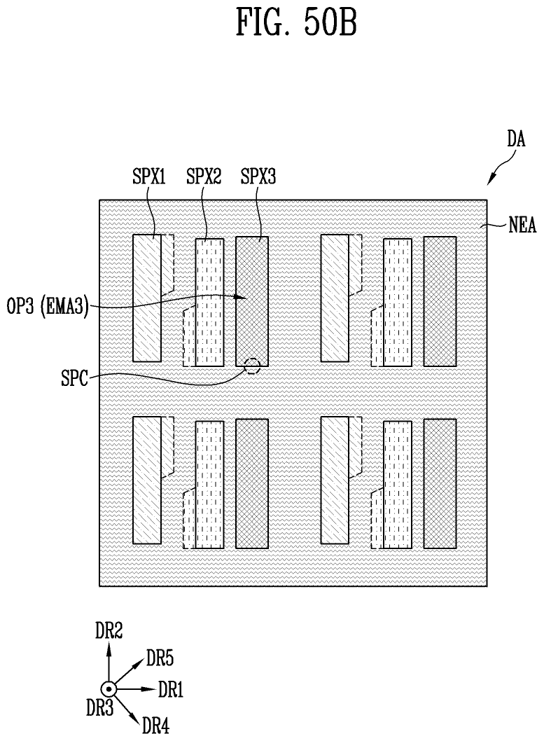

Referring to FIG. 50A, the spacer SPC may be positioned inside the third emission area EMA3 (or to entirely overlap the third emission area EMA3). For example, referring to FIG. 50A, the spacer SPC may be positioned inside the third original area OP3.

Referring to FIG. 50B, at least a portion of the spacer SPC may be positioned inside the third emission area EMA3. For example, referring to FIG. 50B, at least a portion of the spacer SPC may be positioned inside the third original area OP3, and a remaining portion of the spacer SPC may be positioned in the non-emission area NEA.

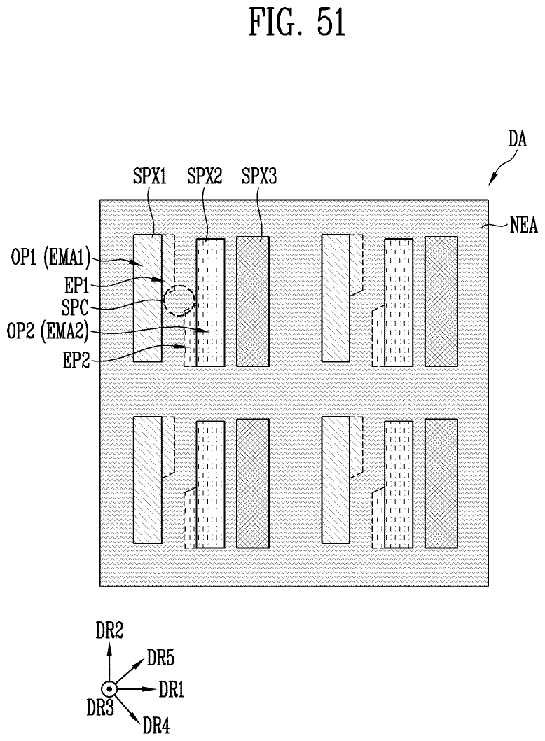

Referring to FIG. 51, the spacer SPC may overlap the first and second sub-pixels SPX1 and SPX2.

Referring to FIG. 51, at least a portion of the spacer SPC may be positioned inside the first expansion area EP1, and at least a portion of the spacer SPC may be positioned inside the second expansion area EP2. A remaining portion of the spacer SPC may be positioned in the non-emission area NEA positioned between the first and second sub-pixels SPX1 and SPX2. However, embodiments of the disclosure are not limited thereto. For example, at least a portion of the spacer SPC may be positioned inside the first original area OP1. At least a portion of the spacer SPC may be positioned inside the second original area OP2.

In an embodiment, the spacer SPC may overlap the first and third sub-pixels SPX1 and SPX3, or may overlap the second and third sub-pixels SPX2 and SPX3.

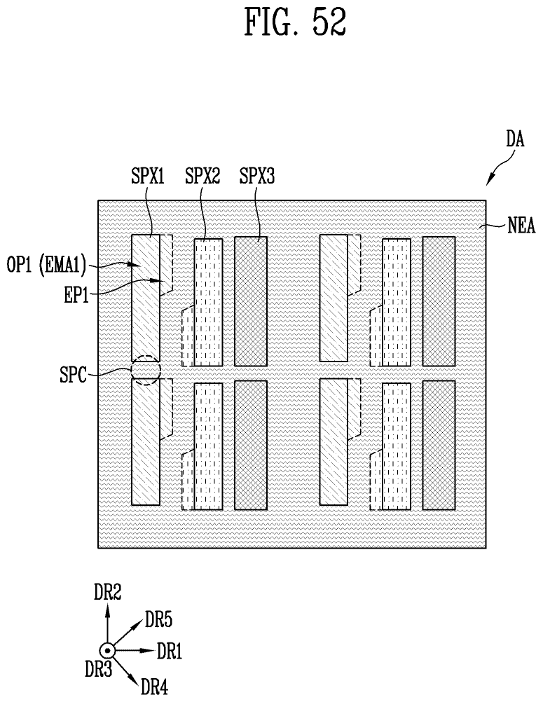

Referring to FIG. 52, the spacer SPC may overlap the first sub-pixels SPX1.

In the above embodiment, at least a portion of the spacer SPC may be positioned inside the first emission area EMA1 of one of two first sub-pixels SPX1 adjacent to each other in the second direction DR2. A remaining portion of the spacer SPC may be positioned inside the first emission area EMA1 of remaining one of the two first sub-pixels SPX1 adjacent to each other in the second direction DR2. For example, referring to FIG. 52, at least a portion of the spacer SPC may be positioned inside the first original area OP1. A remaining portion of the spacer SPC may be positioned in the non-emission area NEA. However, embodiments of the disclosure are not limited thereto. In an embodiment, the spacer SPC may overlap the second sub-pixels SPX2, or may overlap the third sub-pixels SPX3.

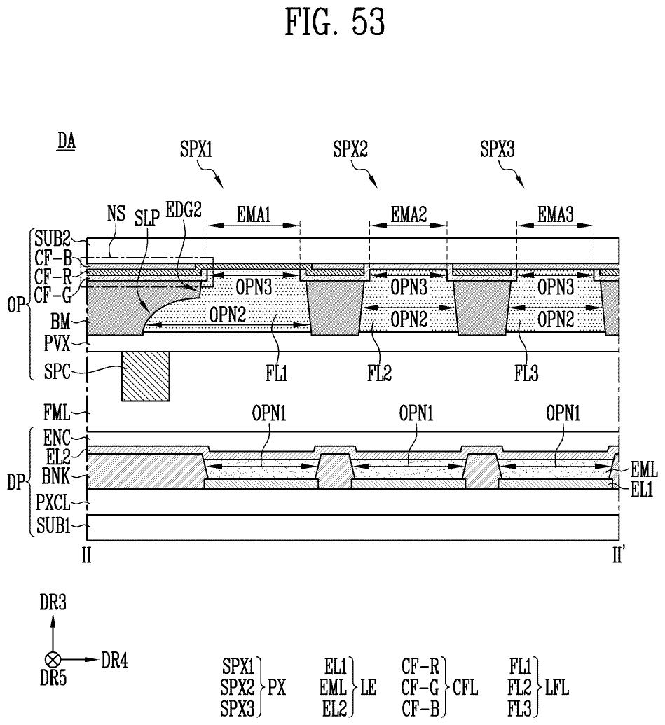

FIGS. 53 to 64 are other examples of a schematic cross-sectional view taken along line II-II′ of FIG. 3.

Referring to FIG. 53, the black matrix BM according to embodiments of the disclosure may include a slope surface SLP.

The slope surface SLP may configure at least a portion of a side surface of the second opening OPN2 by removing at least a portion of the black matrix BM. The light functional layer LFL may be positioned on the slope surface SLP. For example, referring to FIG. 53, the first functional layer FL1 may be positioned on the slope surface SLP. However, embodiments of the disclosure are not limited thereto, and the second functional layer FL2 may be positioned or the third functional layer FL3 may be positioned on the slope surface SLP.

In an embodiment, the slope surface SLP may extend to the second edge portion EDG2. However, embodiments of the disclosure are not limited thereto. For example, the slope surface SLP may be connected (e.g., directly connected) to the overlap structure NS.

In an embodiment, the slope surface SLP may be formed by etching the black matrix BM using a photoresist process. For example, the slope surface SLP may be formed in the black matrix BM by forming multiple slits in a photoresist correspondingly to an area where the slope surface SLP may be formed, and irradiating light through the formed slits.

In an embodiment, at least two of the slits formed in the photoresist may have different widths. In an embodiment, the slits formed in the photoresist may be disposed at different distances. However, a method of forming the slope surface SLP is not limited to that described above.

The spacer SPC may overlap the slope surface SLP in the third direction DR3. The overlap structure NS may overlap the slope surface SLP in the third direction DR3. However, embodiments of the disclosure are not limited thereto.

In the above embodiment, a width of the second opening OPN2 of the sub-pixel (for example, the first sub-pixel SPX1) may be widened. According to this, a volume of the light functional layer LFL may be increased. Accordingly, color conversion efficiency may be increased or light scattering efficiency may be increased.

In an embodiment of FIG. 53, the black matrix BM and the spacer SPC may be disposed on the optical panel OP.

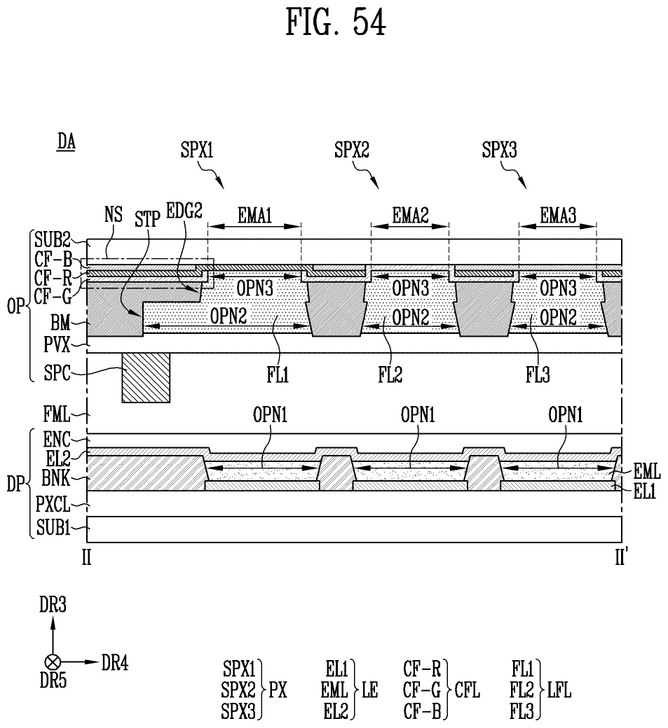

Referring to FIG. 54, the black matrix BM according to embodiments of the disclosure may include a step STP.

The step STP may configure at least a portion of a side surface and a lower surface of the second opening OPN2 by removing at least a portion of the black matrix BM. The light functional layer LFL may be positioned on the step STP. For example, referring to FIG. 54, the first functional layer FL1 may be positioned on the step STP. However, embodiments of the disclosure are not limited thereto, and the second functional layer FL2 may be positioned or the third functional layer FL3 may be positioned on the step STP.

In an embodiment, the step STP may extend to the second edge portion EDG2.

In an embodiment, the step STP may be formed by etching the black matrix BM using a photoresist process. For example, the step STP may be formed in the black matrix BM by forming a slit in a photoresist correspondingly to an area where the step STP may be formed and irradiating light through the formed slits.

The spacer SPC may overlap the step STP in the third direction DR3. The overlap structure NS may overlap the step STP in the third direction DR3. However, embodiments of the disclosure are not limited thereto.

In the above embodiment, the width of the second opening OPN2 of the sub-pixel (for example, the first sub-pixel SPX1) may be widened. According to this, the volume of the light functional layer LFL may be increased. Accordingly, color conversion efficiency may be increased or light scattering efficiency may be increased.

In an embodiment of FIG. 54, the black matrix BM and the spacer SPC may be disposed on the optical panel OP. The spacer SPC may overlap the side surface of the second opening OPN2 in the third direction DR3.

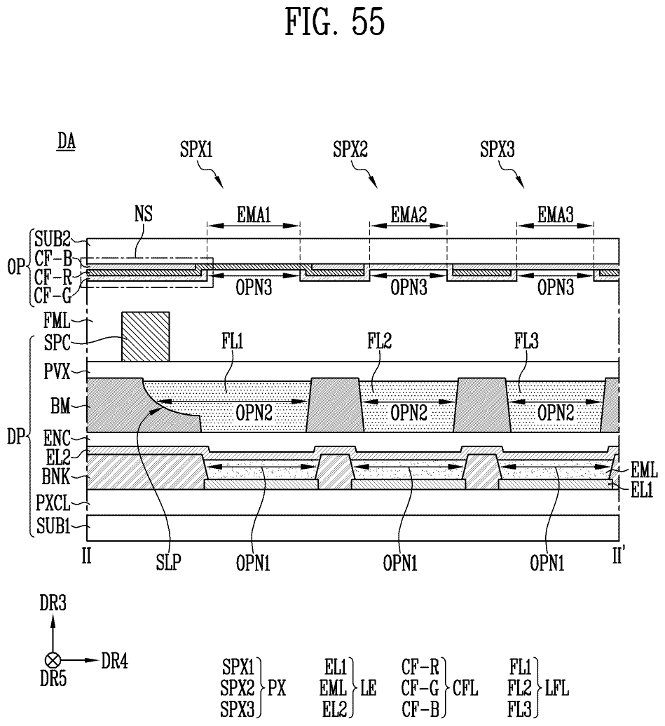

Referring to FIG. 55, the black matrix BM may include the slope surface SLP. The display panel DP according to embodiments of the disclosure may include the black matrix BM and the spacer SPC. The spacer SPC may overlap the side surface of the second opening OPN2 in the third direction DR3.

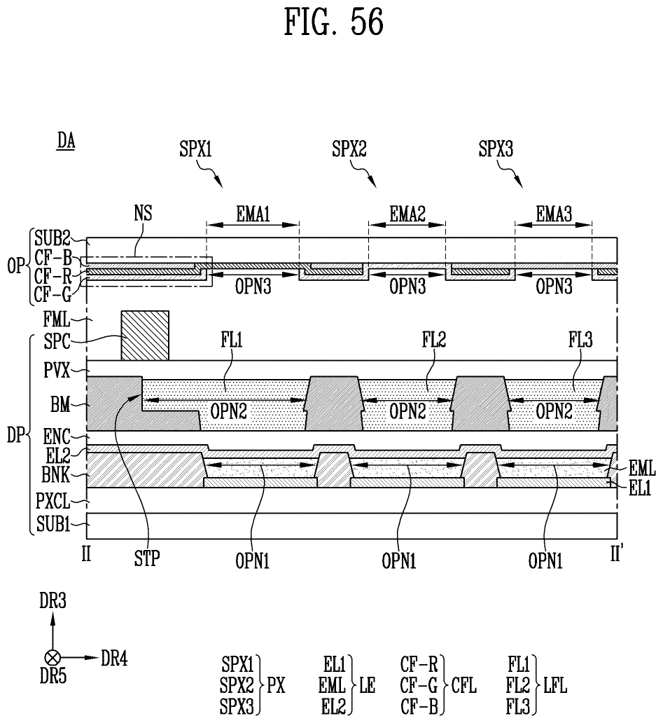

Referring to FIG. 56, the black matrix BM may include the step STP. The display panel DP according to embodiments of the disclosure may include the black matrix BM and the spacer SPC. The spacer SPC may overlap the side surface of the second opening OPN2 in the third direction DR3.

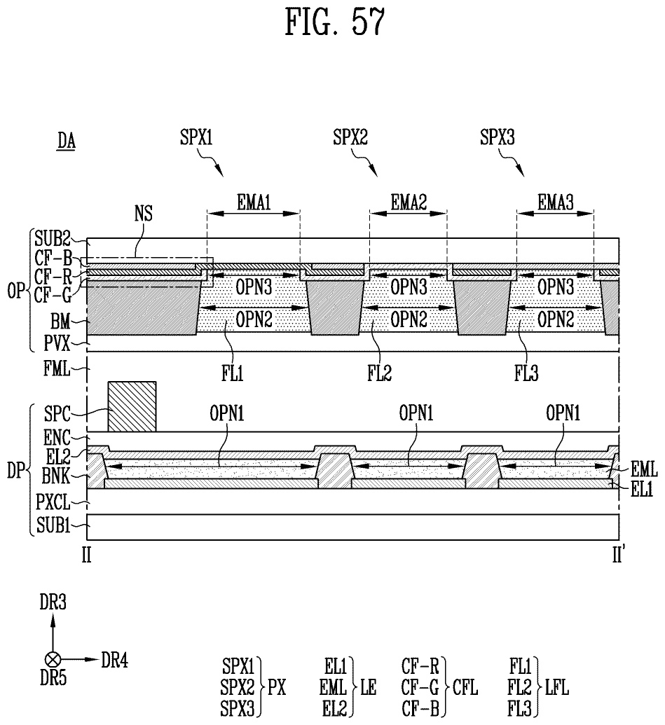

Referring to FIGS. 57 to 64, the spacer SPC may overlap at least one of the first to third openings OPN1, OPN2, and OPN3 and may not overlap at least one of the remaining openings OPN1, OPN2, and OPN3.

Referring to FIG. 57, the spacer SPC may overlap the first opening OPN1 in the third direction DR3. The spacer SPC may not overlap the second and third openings OPN2 and OPN3. For example, the spacer SPC may overlap the first opening OPN1 of the first sub-pixel SPX1. However, embodiments of the disclosure are not limited thereto, and the spacer SPC may overlap the first opening OPN1 of the second sub-pixel SPX2 or may overlap the first opening OPN1 of the third sub-pixel SPX3.

According to the above embodiment, a width of the first opening OPN1 may be increased. According to this, by increasing a size of the light emitting element LE, an amount of light emitted from the light emitting element LE may be increased. Accordingly, display quality may be improved.

In embodiments of the disclosure, the display panel DP may include the spacer SPC. The optical panel OP may include the black matrix BM.

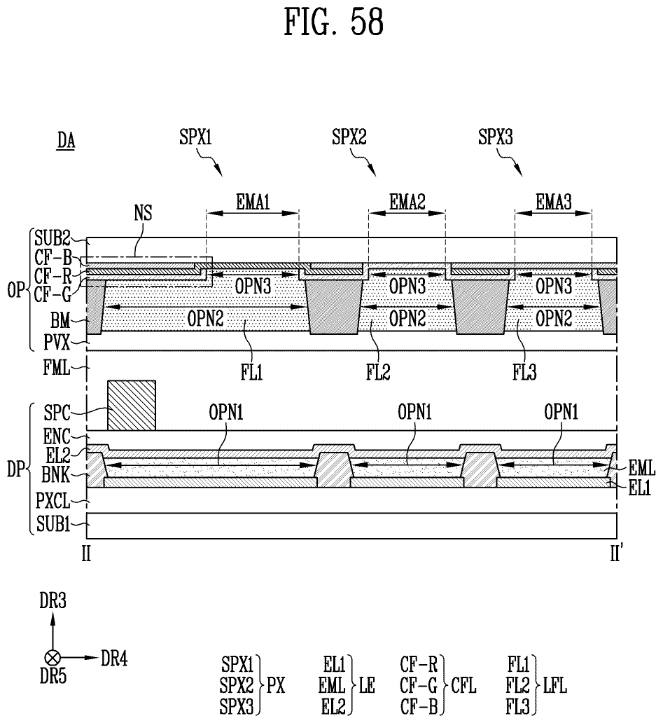

Referring to FIG. 58, the spacer SPC may overlap the first and second openings OPN1 and OPN2 in the third direction DR3 (or in a plan view). The spacer SPC may not overlap the third opening OPN3. For example, the spacer SPC may overlap the first and second openings OPN1 and OPN2 of the first sub-pixel SPX1. However, embodiments of the disclosure are not limited thereto, and the spacer SPC may overlap the first and second openings OPN1 and OPN2 of the second sub-pixel SPX2. As an embodiment, the spacer SPC may overlap the first and second openings OPN1 and OPN2 of the third sub-pixel SPX3.

According to the above embodiment, the width of the first opening OPN1 may be increased. According to this, by increasing the size of the light emitting element LE, an amount of light emitted from the light emitting element LE may be increased. Accordingly, display quality may be improved.

According to the above embodiment, the width of the second opening OPN2 may be increased. According to this, by increasing the volume of the light functional layer LFL, the amount of the light color converted or scattered by the light functional layer LFL may be increased. Accordingly, display quality may be improved.

In embodiments of the disclosure, the display panel DP may include the spacer SPC. The optical panel OP may include the black matrix BM.

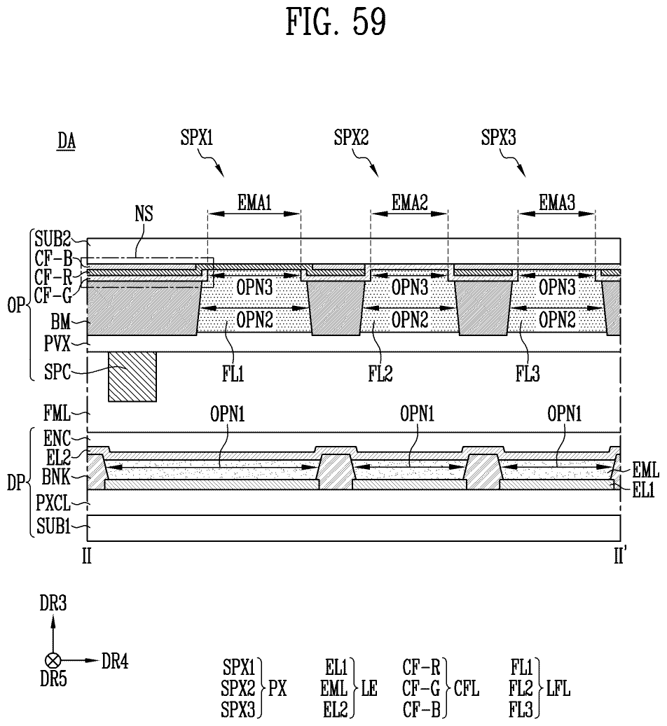

Referring to FIG. 59, the spacer SPC may overlap the first opening OPN1 in the third direction DR3. The spacer SPC may not overlap the second and third openings OPN2 and OPN3. For example, the spacer SPC may overlap the first opening OPN1 of the first sub-pixel SPX1. However, embodiments of the disclosure are not limited thereto, and the spacer SPC may overlap the first opening OPN1 of the second sub-pixel SPX2 or may overlap the first opening OPN1 of the third sub-pixel SPX3.

According to the above embodiment, the width of the first opening OPN1 may be increased. According to this, by increasing the size of the light emitting element LE, the amount of light emitted from the light emitting element LE may be increased. Accordingly, display quality may be improved.

In embodiments of the disclosure, the optical panel OP may include the spacer SPC and the black matrix BM.

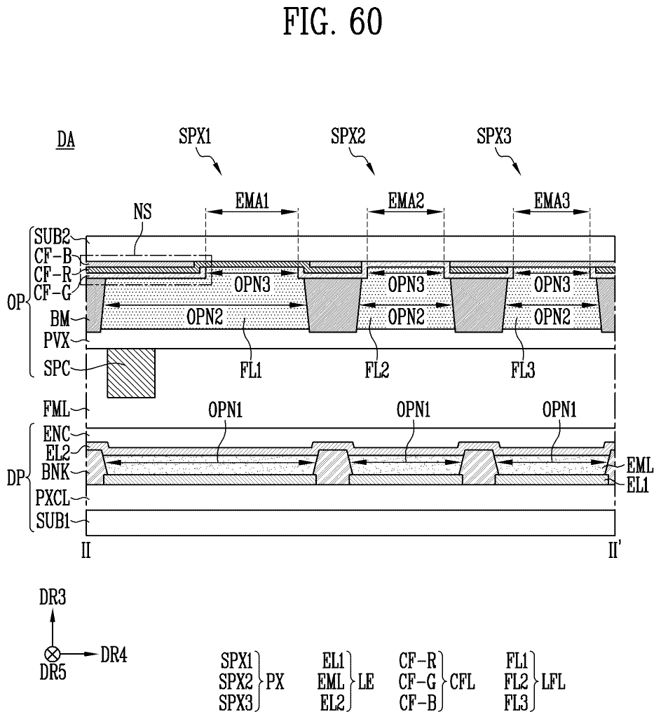

Referring to FIG. 60, the spacer SPC may overlap the first and second openings OPN1 and OPN2 in the third direction DR3. The spacer SPC may not overlap the third opening OPN3. For example, the spacer SPC may overlap the first and second openings OPN1 and OPN2 of the first sub-pixel SPX1. However, embodiments of the disclosure are not limited thereto, and the spacer SPC may overlap the first and second openings OPN1 and OPN2 of the second sub-pixel SPX2. As an embodiment, the spacer SPC may overlap the first and second openings OPN1 and OPN2 of the third sub-pixel SPX3.

According to the above embodiment, the width of the first opening OPN1 may be increased. According to this, by increasing the size of the light emitting element LE, the amount of light emitted from the light emitting element LE may be increased. Accordingly, display quality may be improved.

According to the above embodiment, the width of the second opening OPN2 may be increased. According to this, by increasing the volume of the light functional layer LFL, the amount of light color converted or scattered by the light functional layer LFL may be increased. Accordingly, display quality may be improved.

In embodiments of the disclosure, the optical panel OP may include the spacer SPC and the black matrix BM.

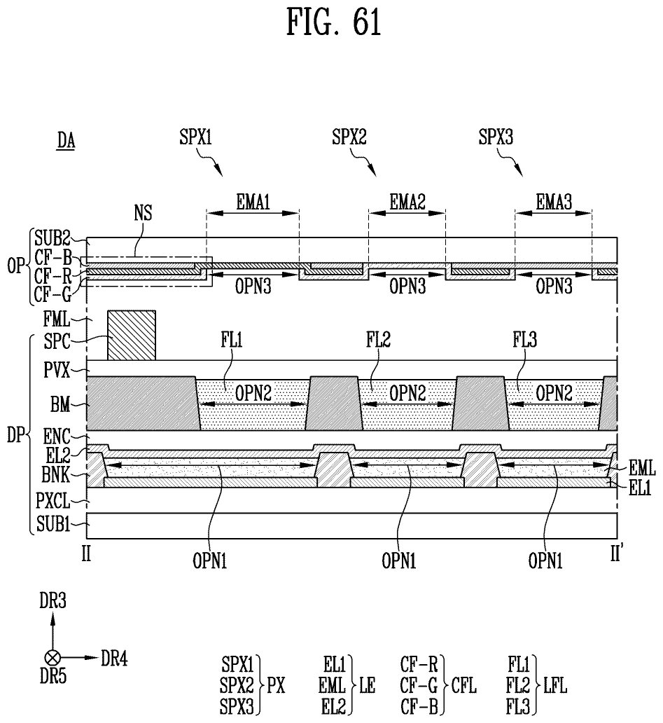

Referring to FIG. 61, the spacer SPC may overlap the first opening OPN1 in the third direction DR3. The spacer SPC may not overlap the second and third openings OPN2 and OPN3. For example, the spacer SPC may overlap the first opening OPN1 of the first sub-pixel SPX1. However, embodiments of the disclosure are not limited thereto, and the spacer SPC may overlap the first opening OPN1 of the second sub-pixel SPX2 or may overlap the first opening OPN1 of the third sub-pixel SPX3.

According to the above embodiment, the width of the first opening OPN1 may be increased. According to this, by increasing the size of the light emitting element LE, the amount of light emitted from the light emitting element LE may be increased. Accordingly, display quality may be improved.

In embodiments of the disclosure, the display panel DP may include the black matrix BM and the spacer SPC.

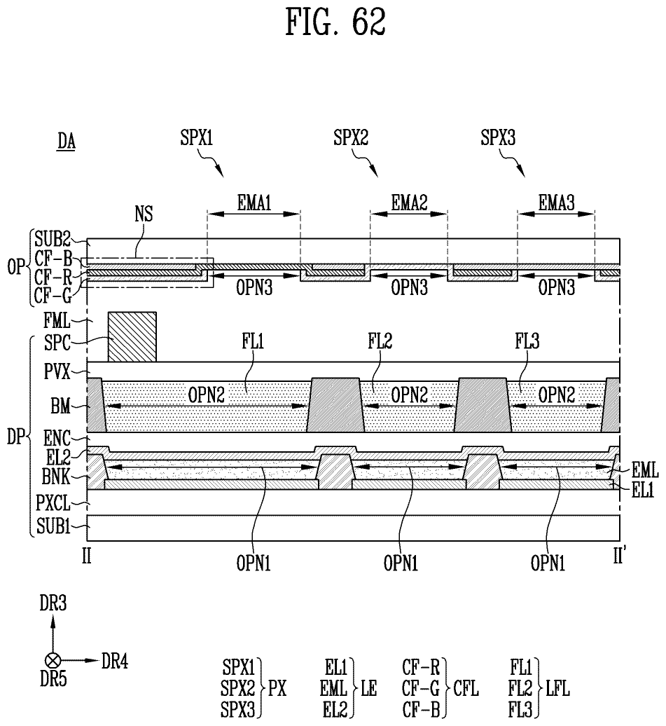

Referring to FIG. 62, the spacer SPC may overlap the first and second openings OPN1 and OPN2 in the third direction DR3. The spacer SPC may not overlap the third opening OPN3. For example, the spacer SPC may overlap the first and second openings OPN1 and OPN2 of the first sub-pixel SPX1. However, embodiments of the disclosure are not limited thereto, and the spacer SPC may overlap the first and second openings OPN1 and OPN2 of the second sub-pixel SPX2. As an embodiment, the spacer SPC may overlap the first and second openings OPN1 and OPN2 of the third sub-pixel SPX3.

According to the above embodiment, the width of the first opening OPN1 may be increased. According to this, by increasing the size of the light emitting element LE, the amount of light emitted from the light emitting element LE may be increased. Accordingly, display quality may be improved.

According to the above embodiment, the width of the second opening OPN2 may be increased. According to this, by increasing the volume of the light functional layer LFL, the amount of light color converted or scattered by the light functional layer LFL may be increased. Accordingly, display quality may be improved.

In embodiments of the disclosure, the display panel DP may include the black matrix BM and the spacer SPC.

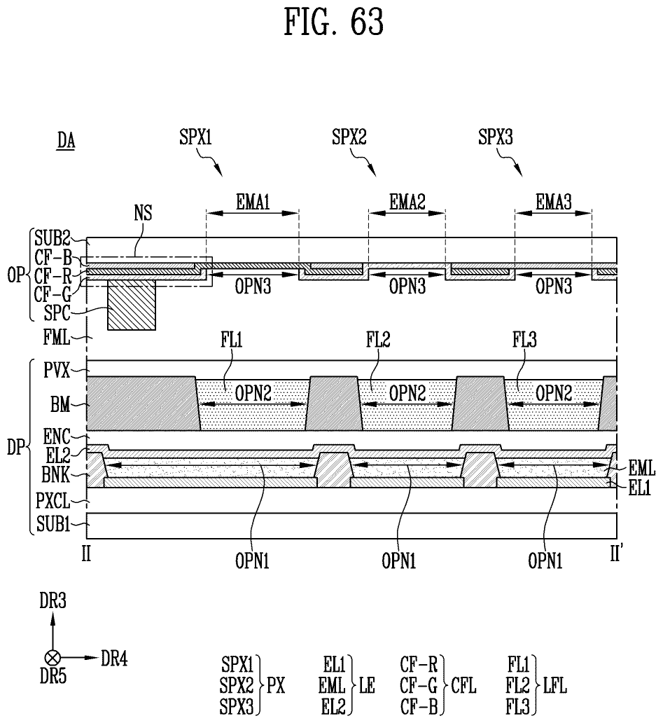

Referring to FIG. 63, the spacer SPC may overlap the first opening OPN1 in the third direction DR3. The spacer SPC may not overlap the second and third openings OPN2 and OPN3. For example, the spacer SPC may overlap the first opening OPN1 of the first sub-pixel SPX1. However, embodiments of the disclosure are not limited thereto, and the spacer SPC may overlap the first opening OPN1 of the second sub-pixel SPX2 or may overlap the first opening OPN1 of the third sub-pixel SPX3.

According to the above embodiment, the width of the first opening OPN1 may be increased. According to this, by increasing the size of the light emitting element LE, the amount of light emitted from the light emitting element LE may be increased. Accordingly, display quality may be improved.

In embodiments of the disclosure, the optical panel OP may include the spacer SPC. The display panel DP may include the black matrix BM.

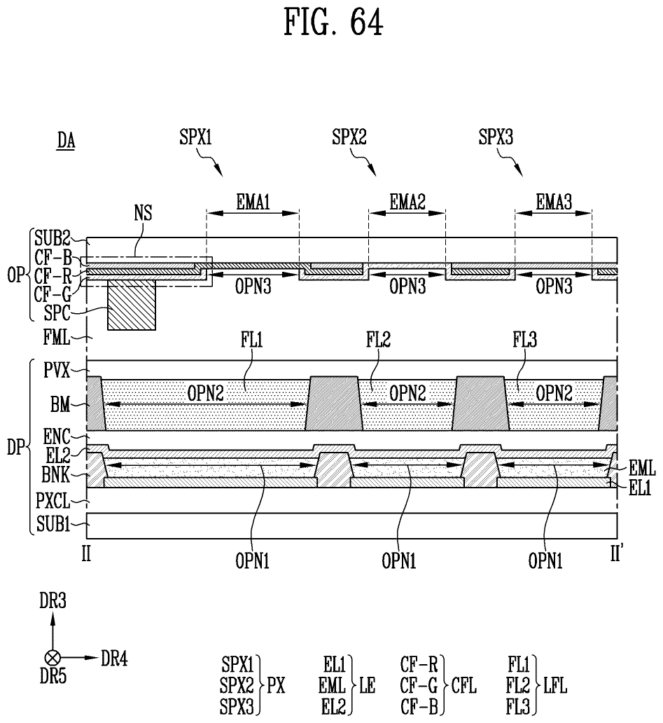

Referring to FIG. 64, the spacer SPC may overlap the first and second openings OPN1 and OPN2 in the third direction DR3. The spacer SPC may not overlap the third opening OPN3. For example, the spacer SPC may overlap the first and second openings OPN1 and OPN2 of the first sub-pixel SPX1. However, embodiments of the disclosure are not limited thereto, and the spacer SPC may overlap the first and second openings OPN1 and OPN2 of the second sub-pixel SPX2. As an embodiment, the spacer SPC may overlap the first and second openings OPN1 and OPN2 of the third sub-pixel SPX3.

According to the above embodiment, the width of the first opening OPN1 may be increased. According to this, by increasing the size of the light emitting element LE, the amount of light emitted from the light emitting element LE may be increased. Accordingly, display quality may be improved.

According to the above embodiment, the width of the second opening OPN2 may be increased. According to this, by increasing the volume of the light functional layer LFL, the amount of light color converted or scattered by the light functional layer LFL may be increased. Accordingly, display quality may be improved.

In embodiments of the disclosure, the optical panel OP may include the spacer SPC. The display panel DP may include the black matrix BM.

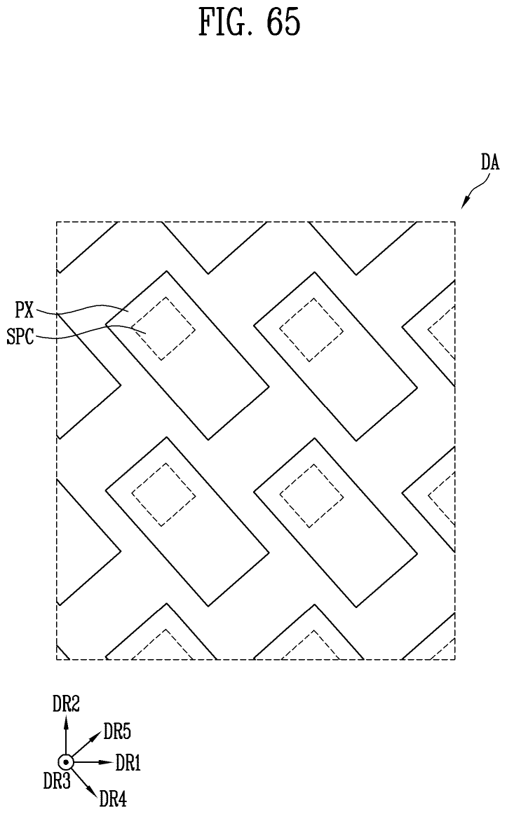

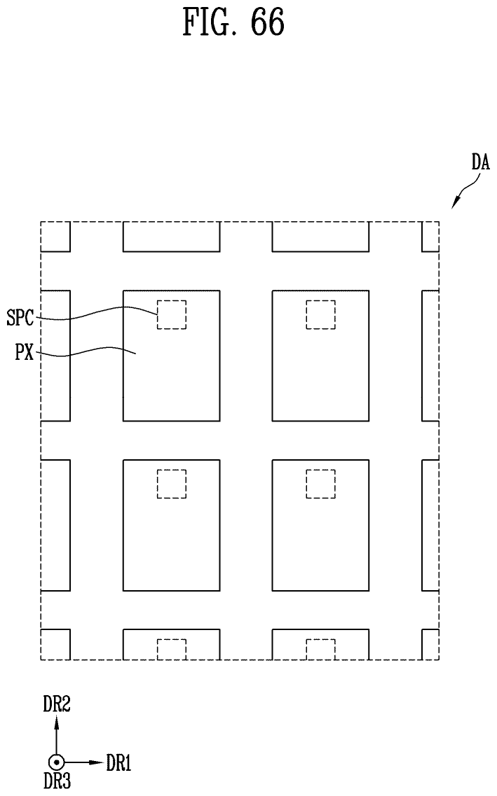

FIGS. 65 and 66 are schematic diagrams illustrating different shapes of the spacer SPC disposed in the display area DA.

Multiple pixels PX may be disposed in the display area DA. The pixels PX may be adjacent to each other in the first direction DR1 and the second direction DR2.

Each of the pixels PX may entirely have a quadrangular shape (or close to a quadrangular shape).

In an embodiment, a cross-sectional shape of the spacer SPC may be a quadrangular shape. However, embodiments of the disclosure are not limited thereto. For example, the cross-sectional shape of the spacer SPC may be a triangular shape or a polygonal shape such as a pentagonal shape or more.

Referring to FIG. 65, each side of a cross section of the spacer SPC may extend in one of the fourth direction DR4 and the fifth direction DR5. However, embodiments of the disclosure are not limited thereto.

Referring to FIG. 66, each side of the cross section of the spacer SPC may extend in one of the first direction DR1 and the second direction DR2. However, embodiments of the disclosure are not limited thereto.

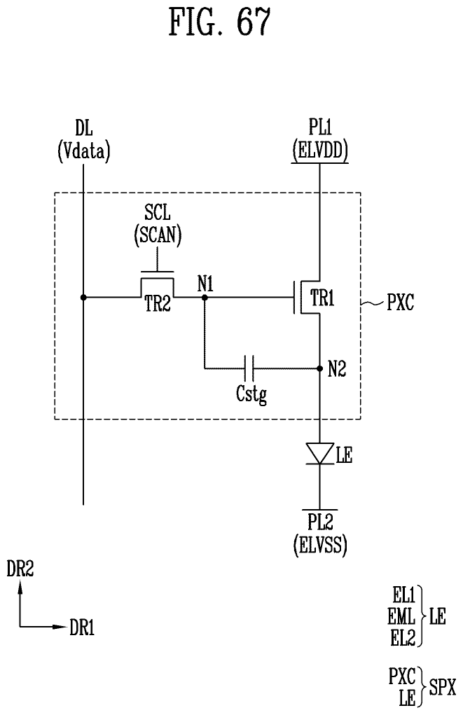

FIG. 67 is an example schematic diagram of an equivalent circuit of a sub-pixel SPX according to embodiments of the disclosure.

Referring to FIG. 67, the sub-pixel SPX according to embodiments of the disclosure may include a pixel circuit PXC and the light emitting element LE.

The pixel circuit PXC may be included in the above-described pixel circuit layer PXCL (refer to FIG. 3).

The pixel circuit PXC may include two or more transistors and at least one capacitor. For example, referring to FIG. 67, the pixel circuit PXC may include a first transistor TR1, a second transistor TR2, and a storage capacitor Cstg.

The first transistor TR1 may include a first electrode (for example, a gate electrode) connected to a first node N1, a second electrode (for example, one of a source electrode and a drain electrode) electrically connected to a first power line PL1, and a third electrode (for example, another of the source electrode and the drain electrode) electrically connected to the second node N2. The first transistor TR1 may generate a current (for example, a driving current) flowing in a direction from the first power line PL1 to the second node N2 (or to the second power line PL2) in response to a voltage applied to the first node N1. The first transistor TR1 may be referred to as a driving transistor.

A first power voltage ELVDD may be applied to the first power line PL1. A second power voltage ELVSS may be applied to the second power line PL2. The first power voltage ELVDD may be a voltage of relatively high potential. The second power voltage ELVSS may be a voltage of relatively low potential. In an embodiment, the first power line PL1 may be disposed to extend entirely in the second direction DR2. In an embodiment, the second power line PL2 may be disposed to extend entirely in the second direction DR2. However, embodiments of the disclosure are not limited thereto.

The first transistor TR1 may be implemented as a transistor including an N-type semiconductor layer, or may be implemented as a transistor including a P-type semiconductor layer. For example, referring to FIG. 67, an embodiment in which the first transistor TR1 may be implemented as a transistor including an N-type semiconductor layer may be shown. However, embodiments of the disclosure are not limited thereto.

The second transistor TR2 may be configured to switch an electrical connection between a data line DL and the first node N1 in response to a scan signal SCAN applied to a scan line SCL. Referring to FIG. 67, the second transistor TR2 may electrically connect the data line DL and the first node N1 in response to a turn-on level of scan signal SCAN. In case that the second transistor TR2 is turned on, a data voltage Vdata or a voltage corresponding thereto may be applied to the first node N1.

The data voltage Vdata may be applied to the data line DL. The data line DL may extend entirely in the second direction DR2.

The scan signal SCAN may be applied to the scan line SCL. The scan line SCL may extend entirely in the first direction DR1.

The storage capacitor Cstg may be configured to maintain a voltage difference between the first node N1 and the second node N2. The storage capacitor Cstg may include a side (e.g., single side) electrode electrically connected to the first node N1 and another side electrode electrically connected to the second node N2. Both side electrodes may be disposed to face each other.

The light emitting element LE may include the first electrode EL1 connected to the second node N2, the second electrode EL2 connected to the second power line PL2, and the light emitting layer EML disposed between the first electrode EL1 and the second electrode EL2. For example, the first electrode EL1 may be an anode electrode. For example, the second electrode EL2 may be a cathode electrode. For example, the light emitting element LE may be implemented as an organic light emitting element. However, embodiments of the disclosure are not limited thereto.

According to a display device according to embodiments of the disclosure, a display panel and an optical panel may be protected.

According to the display device according to embodiments of the disclosure, an aperture ratio may be increased.

According to the display device according to embodiments of the disclosure, emission efficiency may be increased.

The drawings referred to so far and the detailed description of the disclosure described herein are merely examples of the disclosure, are used for merely describing the disclosure, and are not intended to limit the meaning and the scope of the disclosure described in claims. Therefore, those skilled in the art will understand that various modifications and equivalent other embodiments are possible from these. Thus, the true scope of the disclosure should be determined by the technical spirit of the appended claims.

What is claimed is:

1. A display device comprising:
a substrate;
a pixel circuit layer disposed on the substrate and including a pixel circuit;
a bank layer disposed on the pixel circuit layer and including a first opening;
a light emitting element including a light emitting layer disposed inside the first opening;
an encapsulation layer covering the light emitting element;
a black matrix disposed on the light emitting element and including a second opening;
a light functional layer disposed inside the second opening;
a color filter layer including a first color filter, a second color filter, and a third color filter, the color filter layer further including a third opening surrounded by a nested structure where the first to third color filters overlap, wherein one of the first to third color filters is disposed in the third opening; and
a spacer, wherein at least a portion of the spacer overlaps the second opening.

2. The display device of claim 1, wherein the spacer further overlaps at least one of the first opening and the third opening.

3. The display device of claim 1, wherein the light functional layer comprises:
a first functional layer overlapping the first color filter and that converts to light of a first wavelength band and emit light of the first wavelength band;
a second functional layer overlapping the second color filter and that converts to light of a second wavelength band different from the first wavelength band and emit light of the second wavelength band; and
a third functional layer overlapping the third color filter and that scatters light.

4. The display device of claim 3, wherein
the first wavelength band is a red wavelength band, and
the second wavelength band is a green wavelength band.

5. The display device of claim 1, wherein
the third opening corresponds to an emission area, and
at least a portion of the spacer overlaps the emission area.

6. The display device of claim 1, wherein
the display device includes:
a filling layer;
a display panel including the substrate and the encapsulation layer; and
an optical panel including the color filter layer,
the filling layer is disposed between the display panel and the optical panel, and
the spacer is surrounded by the filling layer.

7. The display device of claim 6, wherein the display panel further includes the spacer.

8. The display device of claim 7, wherein the spacer contacts the encapsulation layer and is covered by the filling layer.

9. The display device of claim 7, wherein
the display panel includes:
the black matrix;
a passivation layer; and
the light functional layer,
the passivation layer covers the black matrix and the light functional layer, and
the spacer is disposed between the passivation layer and the filling layer.

10. The display device of claim 6, wherein the optical panel includes the spacer.

11. The display device of claim 10, wherein
the spacer contacts the color filter layer, and
the spacer is covered by the filling layer.

12. The display device of claim 10, wherein
the optical panel includes the black matrix and the light functional layer,
the optical panel further includes a passivation layer covering the black matrix and the light functional layer, and
the spacer is disposed between the passivation layer and the filling layer.

13. The display device of claim 1, wherein
the first opening is surrounded by a sloped first edge portion of the bank layer, and
the spacer overlaps the sloped first edge portion of the bank layer.

14. The display device of claim 1, wherein
the second opening is surrounded by a sloped second edge portion of the black matrix, and
the spacer overlaps the sloped second edge portion of the black matrix.

15. The display device of claim 1, wherein the spacer overlaps a side end portion of the nested structure.

16. The display device of claim 1, wherein
a plurality of pixels disposed on the substrate and adjacent to each other in a first direction,
each of the plurality of pixels comprises:
a first sub-pixel including the first color filter;
a second sub-pixel including the second color filter; and
a third sub-pixel including the third color filter, and
at least a portion of the spacer overlaps the third opening of one of the first to third sub-pixels in a plan view.

17. The display device of claim 16, wherein an entirety of the spacer overlaps the third opening of one of the first to third sub-pixels in a plan view.

18. The display device of claim 16, wherein the spacer overlaps a third opening of at least two of the first to third sub-pixels.

19. The display device of claim 16, wherein
the first sub-pixel and the third sub-pixel are adjacent to each other in the first direction,
the third opening of each of the first sub-pixel and the second sub-pixel has a trapezoidal shape in a plan view,
the third opening of the third sub-pixel has a rectangular shape in a plan view, and
the third openings of the first to third sub-pixels generally have a rectangular shape.

20. The display device of claim 16, wherein
each of the first sub-pixel and the second sub-pixel further extends in a second direction perpendicular to the first direction, and
each of the first sub-pixel and the second sub-pixel are adjacent to the third sub-pixel in the second direction.
